(19) United States
(12) Patent Application Publication
(10) Pub. No.: US 2020/0347226 A1
(43) Pub. Date: Nov. 5, 2020

(54) RESIN COMPOSITION FOR INSULATING FILM

(71) Applicant: NISSAN CHEMICAL CORPORATION, Tokyo (JP)

(72) Inventors: Takuya OHASHI, Toyama-shi (JP); Yosuke IINUMA, Funabashi-shi (JP); Hayato HATTORI, Toyama-shi (JP); Yuki USUI, Toyama-shi (JP); Kazuhiro SAWADA, Toyama-shi (JP)

(73) Assignee: NISSAN CHEMICAL CORPORATION, Tokyo (JP)

(21) Appl. No.: 16/960,451

(22) PCT Filed: Jan. 9, 2019
(86) PCT No.: PCT/JP2019/000319

§ 371 Date: Jul. 7, 2020

(30) Foreign Application Priority Data
Jan. 10, 2018 (JP) 2018-002193

(51) Int. Cl. C08L 79/08; C08K 5/205; C08K 5/31; C08K 5/3445; C08K 5/00

(52) U.S. Cl. CPC C08L 79/085; C08K 5/205; C08K 5/31; C08L 2203/206; C08K 5/0025; C08L 2201/08; C08L 2203/16; C08K 5/3445

(57) ABSTRACT

A resin composition which is for an insulating film and from which a cured product having a further reduced dielectric constant and dielectric loss tangent is obtained; a photosensitive resin composition; a method for producing a cured relief pattern using the photosensitive resin composition; and a semiconductor device with the cured relief pattern. This resin composition for an insulating film includes: a polyimide precursor; and a compound which is a polyimide precursor containing a polyamic acid ester, a thermal imidization accelerator, and a solvent, wherein the thermal imidization accelerator has a carboxyl group and an amino group or imino group which is deprotected by heat and exhibits basicity, and does not accelerate the imidization of the polyimide precursor before the protective group is released. Furthermore, a photosensitive resin composition which is for an insulating film and includes a photopolymerization initiator.

### TECHNICAL FIELD

The present invention relates to a resin composition for an insulating film, preferably a resin composition for an insulating film for semiconductor, a photosensitive resin composition for an insulating film, and a semiconductor device comprising a cured film obtainable by curing the composition.

### BACKGROUND ART

Conventionally, a polyimide resin having excellent heat resistance and excellent electrical properties as well as excellent mechanical properties has been used in insulating materials for electronic parts, and a passivation film, a surface protective film, an interlayer dielectric and others for semiconductor device.

Meanwhile, recently, from the viewpoint of improving the integration degree and operational function and reducing the chip size, the method for mounting a semiconductor device on a printed circuit board has been changing. Instead of a conventional mounting method using a metal pin and a lead-tin eutectic solder, a method using a structure in which a polyimide film is directly in contact with a solder bump, such as BGA (ball grid array) or CSP (chip size packaging), which enables higher-density mounting, has been used. The polyimide film used in forming such a bump structure is required to have high heat resistance and high chemical resistance.

As the semiconductor device has been further miniaturized, a problem of wiring delay has been arisen. A method for improving the wiring resistance of the semiconductor device has been changed from the conventional use of a gold or aluminum wiring to the use of a wiring of copper or a copper alloy having a lower resistance. Further, a method in which the insulation properties between wirings are improved to prevent the occurrence of wiring delay has also been employed. In recent years, as a material having high insulation properties, a low permittivity material frequently constitutes a semiconductor device, but the low permittivity material tends to be brittle and easily broken. For example, when a semiconductor chip including the low permittivity material is mounted on a substrate through a solder reflow step, there is a problem in that the low permittivity material suffers shrinkage due to a change of the temperature, so that the low permittivity material portion is broken.

With respect to the means for solving this problem, Patent Literature 1 discloses a photosensitive resin composition comprising a polyimide precursor which has introduced an aliphatic group having 5 to 30 carbon atoms and having an ethylene glycol structure into a part of the side chain of the polyimide precursor, wherein the photosensitive resin composition has improved transparency, and further a cured film obtained by heat curing the composition has an improved Young's modulus (Patent Literature 1).

A polyimide precursor composition containing an imidization promotor for improving the imidization ratio of polyamic acid is disclosed (Patent Literature 2).

### CITATION LIST

### Patent Literatures

### Patent Literature 1: JP 2013-168675 A

### Patent Literature 2: JP 2010-114103 A

### SUMMARY OF INVENTION

### Technical Problem

The photosensitive resin composition comprising a polyimide precursor disclosed in Patent Literature 1 has high transparency and, after the composition is subjected to heat curing, a cured product having a high Young's modulus can be obtained; however, the cured product of the resin composition is required to exhibit a further reduced permittivity and dielectric loss tangent when used in the above-mentioned applications.

For further reducing the permittivity and dielectric loss tangent of the cured product of the resin composition and improving other performance of the cured product when used as an insulating film, it is necessary to improve the imidization ratio of polyamic acid.

Accordingly, an object of the present invention is to provide a resin composition for an insulating film and a photosensitive resin composition for an insulating film, wherein each of the resin compositions forms a cured product having further reduced permittivity and dielectric loss tangent, a method for producing a cured relief pattern using the photosensitive resin composition for an insulating film, and a semiconductor device comprising the cured relief pattern.

### Solution to Problem

The present inventors have conducted extensive and intensive studies with a view toward achieving the above-mentioned object. As a result, it has been found that a resin composition for an insulating film comprising a polyimide precursor and an imidization promotor having a specific structure can form a cured film having an improved imidization ratio, so that an insulating film exhibiting a low permittivity and a low dielectric loss tangent can be obtained, and the present invention has been completed.

Specifically, the present invention is as follows.

[1] A resin composition for an insulating film, the resin composition comprising:

(A) a polyimide precursor having a unit structure represented by the following general formula (1):

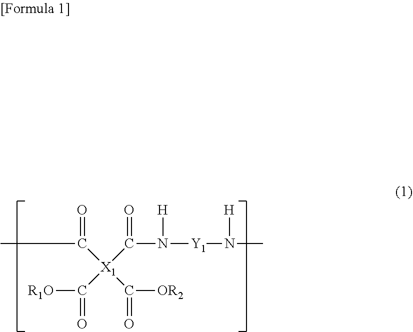

wherein X₁ is a tetravalent organic group having 6 to 40 carbon atoms, Y₁ is a divalent organic group having 6 to 40 carbon atoms, and each of R₁ and R₂ is independently a hydrogen atom or a monovalent organic group selected from the following general formulae (2) and (3):

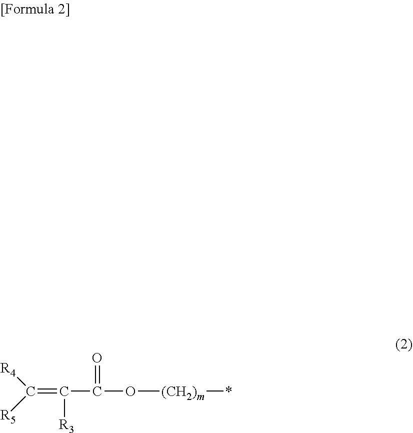

wherein each of R₃, R₄, and R₅ is independently a hydrogen atom or a monovalent organic group having 1 to 3 carbon atoms, m is an integer of 1 to 10, and * is a site bonded to the carboxylic acid present in the polyamic acid main chain of general formula (1),

[Formula 3]

R₆—* (3)

wherein R₆ is a monovalent organic group selected from alkyl groups having 1 to 30 carbon atoms and optionally being interrupted by an ether oxygen atom, and * is as defined above,

wherein a proportion of the total amount of the monovalent organic group represented by general formula (2) above and the monovalent organic group represented by general formula (3) above in the total amount of R₁ and R₂ is 80% by mole or more, and a proportion of the amount of the monovalent organic group represented by general formula (3) above in the total amount of R₁ and R₂ ranges 1 to 100% by mole;

(B) a compound that satisfies all of the following requirements (a) to (d):

(a) having at least one carboxyl group,

(b) having a partial structure represented by formula (N-1) or formula (N-2) below, wherein every structure represented by formula (N-1) is bonded to an aromatic ring or a carbonyl group at at least one site of the structure, or is part of a guanidine scaffold, and every structure represented by formula (N-2) is bonded to a carbon atom having an unsaturated bond at a site of the nitrogen atom, with the proviso that when formula (N-1) is part of a guanidine scaffold, at least one of the two structures (N-1) contained in the guanidine scaffold is bonded to an aromatic ring or a carbonyl group:

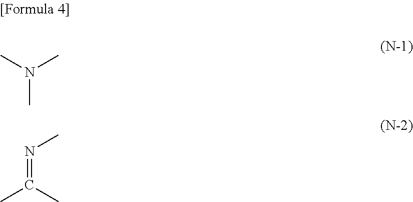

wherein formulae (N-1) and (N-2) represent a trivalent structure in the compound,

(c) at least one partial structure represented by formula (N-1) above being a partial structure of a structure which is represented by the following formula (ND-1), and which is not directly bonded to an aromatic ring and a carbonyl group, or at least one partial structure represented by formula (N-2) above being a partial structure of a structure represented by the following formula (ND-2):

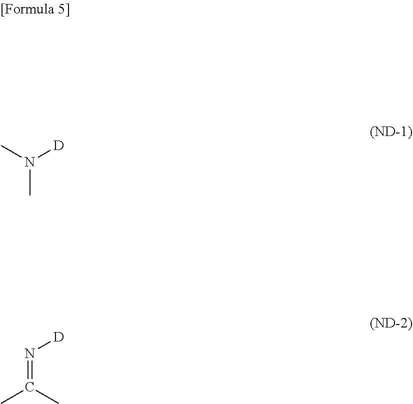

wherein formulae (ND-1) and (ND-2) represent a divalent structure in the compound, and D is a protecting group which is replaceable by a hydrogen atom upon heating,

(d) having, relative to one carboxyl group, at least one structure represented by formula (ND-1) or (ND-2) defined in requirement (c) above; and

(C) an organic solvent.

[2] The resin composition for an insulating film according to [1] above, wherein R₆ is selected from two or more different alkyl groups having 1 to 30 carbon atoms and optionally being interrupted by an ether oxygen atom.

[3] The resin composition for an insulating film according to [1] or [2] above, which is for use in forming a redistribution layer in a production of a semiconductor device.

[4] The photosensitive resin composition for an insulating film according to any one of items [1] to [3] above, which further comprises (D) a photopolymerization initiator.

[5] A resin film for an insulating film, which is a baked product of an applied film comprising the resin composition for an insulating film according to any one of items [1] to [4] above.

[6] A resin film for an insulating film, which is a baked product of an applied film comprising a resin composition for an insulating film, the resin composition comprising:

(A) a polyimide precursor; and

(B) a compound that satisfies all of the following requirements (a) to (d):

(a) having at least one carboxyl group,

(b) having a partial structure represented by formula (N-1) or formula (N-2) below, wherein every structure represented by formula (N-1) is bonded to an aromatic ring or a carbonyl group at at least one site of the structure, or is part of a guanidine scaffold, and every structure represented by formula (N-2) is bonded to a carbon atom having an unsaturated bond at a site of the nitrogen atom, with the proviso that when formula (N-1) is part of a guanidine scaffold, at least one of the two structures (N-1) contained in the guanidine scaffold is bonded to an aromatic ring or a carbonyl group:

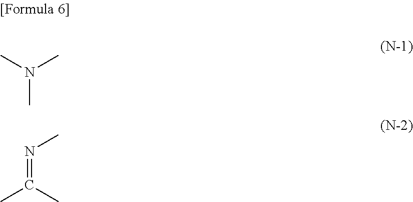

wherein formulae (N-1) and (N-2) represent a trivalent structure in the compound,

(c) at least one partial structure represented by formula (N-1) above being a partial structure of a structure which is represented by the following formula (ND-1), and which is not directly bonded to an aromatic ring and a carbonyl group, or at least one partial structure represented by formula (N-2) above being a partial structure of a structure represented by the following formula (ND-2):

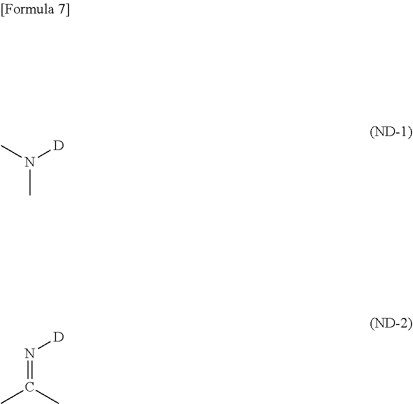

wherein formulae (ND-1) and (ND-2) represent a divalent structure in the compound, and D is a protecting group which is replaceable by a hydrogen atom upon heating,

(d) having, relative to one carboxyl group, at least one structure represented by formula (ND-1) or (ND-2) defined in requirement (c) above,

wherein the resin film has a relative permittivity of 3.5 or less.

[7] A semiconductor device having in at least a part thereof the resin film for an insulating film according to [5] or [6] above.

[8] The resin composition for an insulating film according to [1] above, wherein protecting group D in the compound of component B is an ester group represented by the following formula (5-a):

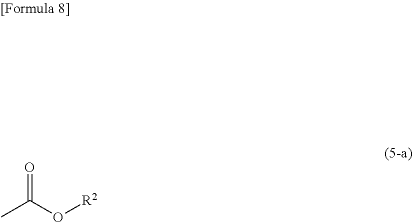

wherein R² is a hydrocarbon having 1 to 22 carbon atoms.

[9] The resin composition for an insulating film according to [8] above, wherein the ester group represented by formula (5-a) is a tert-butoxycarbonyl group or a 9-fluorenylmethoxycarbonyl group.

[10] The resin composition for an insulating film according to any one of items [1] to [4] above, wherein component B is a compound having, relative to one carboxyl group, at least one group of the following formulae (G-1) to (G-7):

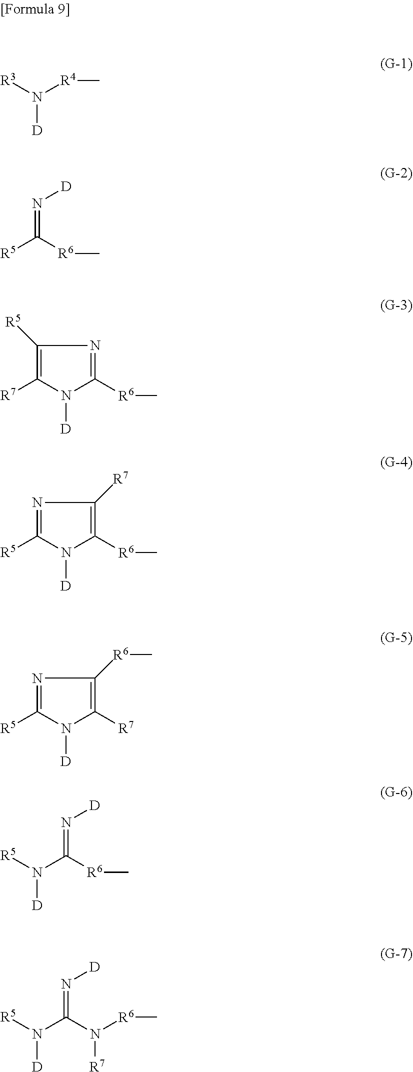

wherein, in formulae (G-1) to (G-7), D is a protecting group which is replaceable by a hydrogen atom upon heating, wherein when a plurality of D's are present, D's are optionally different from each other, and R³ to R⁷ are as follows:
R³ is a hydrogen atom or an organic group having 1 to 30 carbon atoms, wherein the organic group is an alkyl group optionally having a substituent, R⁴ is a single bond or an organic group having 1 to 30 carbon atoms, wherein the organic group is selected from an alkylene group, an alkenylene group, an alkynylene group, and a group comprising a combination thereof, wherein each group optionally has a substituent, with the proviso that when R⁴ is a single bond, the group of formula (G-1) is not directly bonded to an aromatic ring or a carbonyl group,
R⁵ and R⁷ are a hydrogen atom or an organic group having 1 to 30 carbon atoms, wherein the organic group is selected from an alkyl group, an alkenyl group, an alkynyl group, and an aryl group, wherein each group optionally has a substituent, and
R⁶ is a single bond or an organic group having 1 to 30 carbon atoms, wherein the organic group is selected from an alkylene group, an alkenylene group, an alkynylene group, an arylene group, and a group comprising a combination thereof, wherein each group optionally has a substituent,
wherein R₃ to R⁷ are optionally bonded together to form a monocycle or a polycycle.

[11] The resin composition for an insulating film according to [10] above, wherein component B is a compound represented by the following formula (6-a):

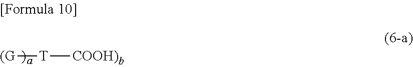

wherein G represents at least one group selected from formulae (G-1) to (G-7), T represents a single bond or an organic group having 1 to 30 carbon atoms, wherein the organic group is a hydrocarbon group optionally having a substituent, a is an integer of 1 to 8, and b is an integer of 1 to 4, wherein a and b satisfy the relationship: a≥b.

[12] The resin composition for an insulating film according to [11] above, wherein component B is a structure represented by the following formula (7-a) or (8-a):

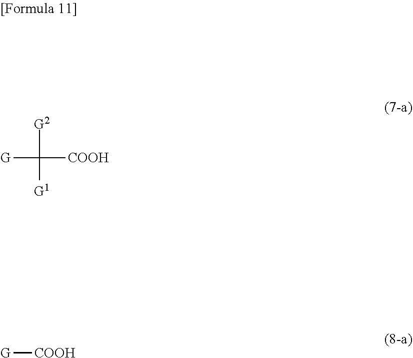

wherein, in formulae (7-a) and (8-a), G represents a group represented by any one of formulae (G-1) to (G-7), and each of G¹ and G² independently represents a hydrogen atom, a group selected from formulae (G-1) to (G-7), or an organic group having 1 to 20 carbon atoms, wherein the organic group is a hydrocarbon optionally having a substituent, with the proviso that when G¹ and G² are not any of the groups of formulae (G-1) to (G-7), the total number of carbon atoms of G¹ and G² is 0 to 29.

[13] The resin composition for an insulating film according to [12] above, wherein component B is at least one compound selected from the following formulae (B-1) to (B-17):

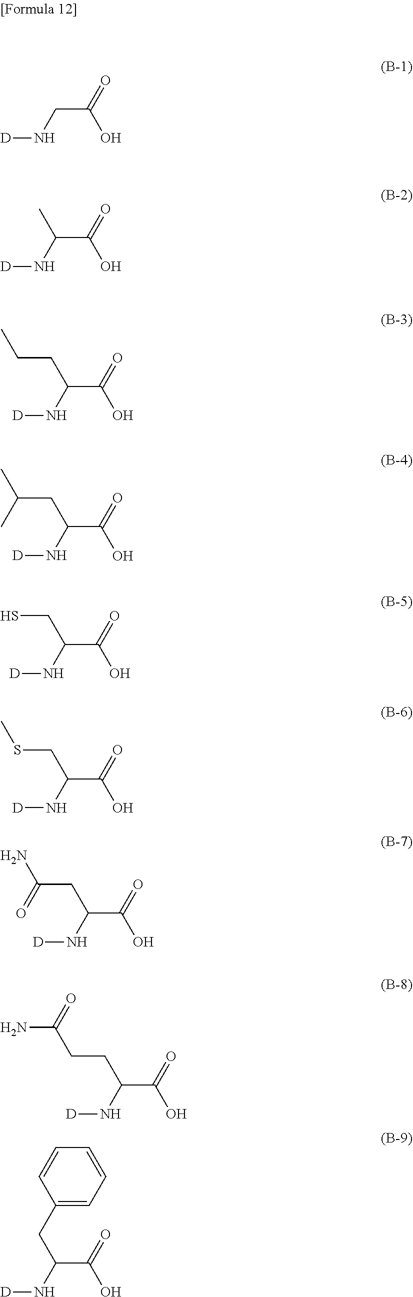

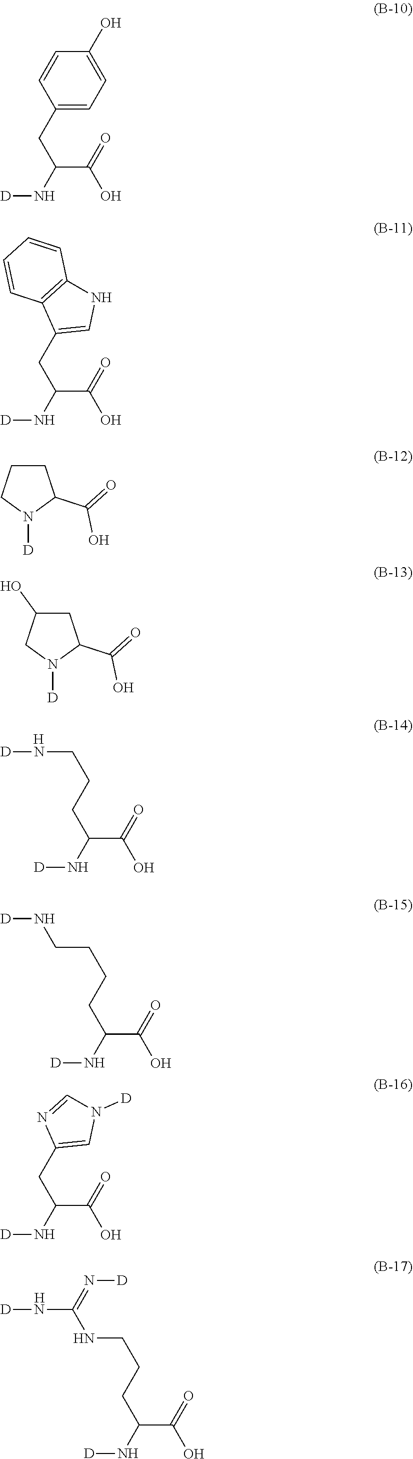

wherein, in formulae (B-1) to (B-17), each D is independently a t-butoxycarbonyl group or a 9-fluorenylmethoxycarbonyl group.

[14] The resin film for an insulating film according to [6] above, wherein polyimide precursor (A) contains, in a polyamic acid ester structure, a structure in which a monovalent organic group is selected from the following general formulae (2) and (3):

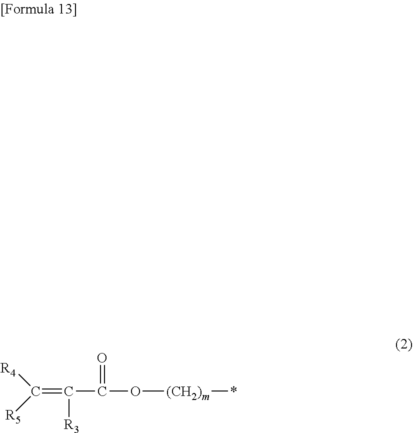

wherein each of R₃, R₄, and R₅ is independently a hydrogen atom or a monovalent organic group having 1 to 3 carbon atoms, m is an integer of 1 to 10, and * is a site bonded to the carboxylic acid present in the polyamic acid main chain of general formula (1),

[Formula 14]

R₆—* (3)
wherein R₆ is a monovalent organic group selected from alkyl groups having 1 to 30 carbon atoms and optionally being interrupted by an ether oxygen atom, and * is as defined above,
   wherein a proportion of the total amount of the monovalent organic group represented by general formula (2) above and the monovalent organic group represented by general formula (3) above in the total amount of R₁ and R₂ is 80% by mole or more, and a proportion of the amount of the monovalent organic group represented by general formula (3) above in the total amount of R₁ and R₂ ranges 1 to 100% by mole.

[15] The photosensitive resin film for an insulating film according to [6] above, which further comprises (D) a photopolymerization initiator.

[16] A semiconductor device having in at least a part thereof the photosensitive resin film for an insulating film according to [15] above.

### Advantageous Effects of Invention

In the present invention, there can be provided a resin composition for an insulating film and a photosensitive resin composition for an insulating film, wherein each of the resin compositions forms a cured product having a low permittivity and a low dielectric loss tangent, a method for producing a cured relief pattern using the photosensitive resin composition for an insulating film, and a semiconductor device comprising the cured relief pattern. Particularly, the resin composition is advantageously used in forming a redistribution layer in the production of a semiconductor device.

### DESCRIPTION OF EMBODIMENTS

[Resin Composition for an Insulating Film]

The resin composition for an insulating film of the present invention comprises (A) a polyimide precursor, (B) a compound that satisfies all of the requirements (a) to (d) shown below, (C) an organic solvent, and, if desired, an additional component. The components of the composition are individually described below.

When the resin composition for an insulating film of the present invention is a negative photosensitive resin composition, the resin composition may further comprise (D) a photopolymerization initiator.

[Polyimide Precursor]

In the embodiment, with respect to polyimide precursor (A), there is no particular limitation as long as the polyimide precursor does not adversely affect the properties of the insulating film formed from the resin composition for an insulating film containing the polyimide precursor as a resin component.

Polyimide precursor (A) used in the present invention is a polymer having a site that is capable of undergoing an imidization reaction shown below.

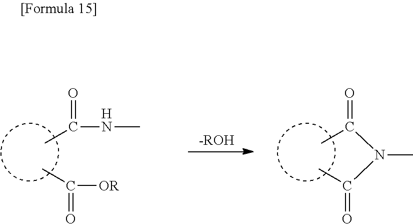

Wherein R represents a monovalent organic group.

The polyimide precursor has, for example, repeating units represented by formula (1-1) below, and undergoes the above-mentioned imidization reaction to form a polyimide having repeating units represented by formula (2-1) below.

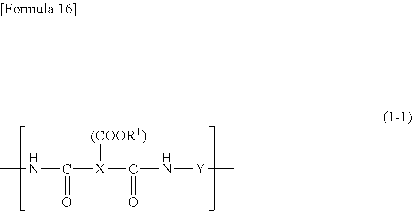

Wherein R¹ represents an alkyl group having 1 to 30 carbon atoms and optionally being interrupted by an ether oxygen atom, X represents a tetravalent organic group, and Y represents a divalent organic group.

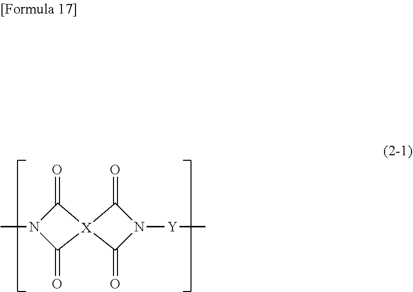

wherein X and Y are as defined above in formula (1-1).

In formula (1-1), R¹ has the same meaning as that of the below-mentioned R₁ and R₂.

In formula (2-1), X is a tetravalent organic group, and should have a structure that can undergo an imidization reaction, together with the ester group and the amide site in formula (1-1). An example of structure of X includes X in a tetracarboxylic dianhydride represented by the following formula (3-a).

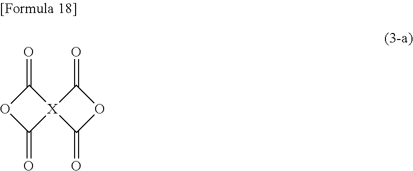

The tetracarboxylic dianhydride represented by formula (3-a) above is reacted with a diamine represented by formula (4-a) below to obtain a polyamic acid, and further the polyamic acid is subjected to cyclodehydration, to obtain a polyimide.

[Formula 19]

H₂N—Y—NH₂ (4-a)

Representative examples of X in the known tetracarboxylic dianhydride represented by formula (3-a) are shown below, but the present invention is not limited to these examples. Further, the polyimide precursor represented by formula (1-1) may be a copolymer in which X comprises two or more different structures.

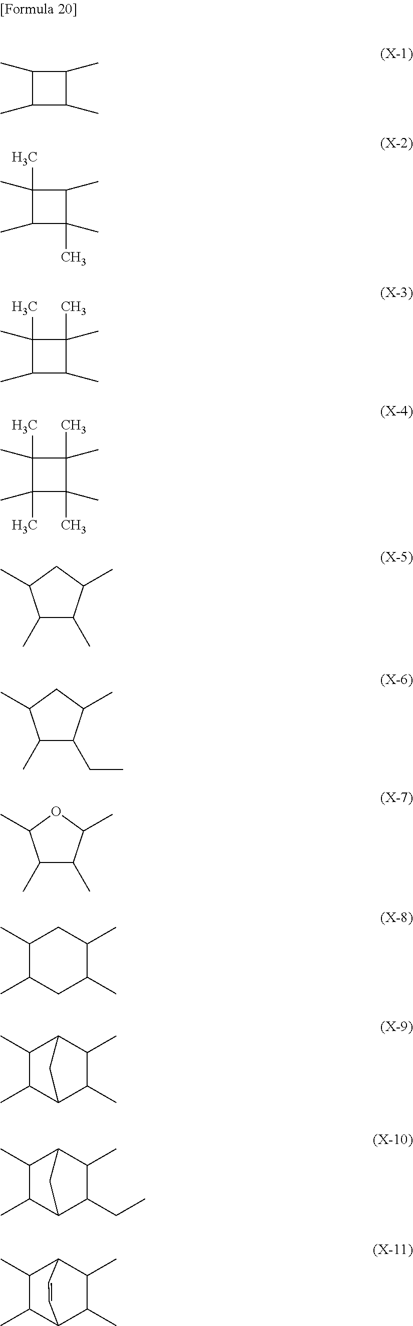

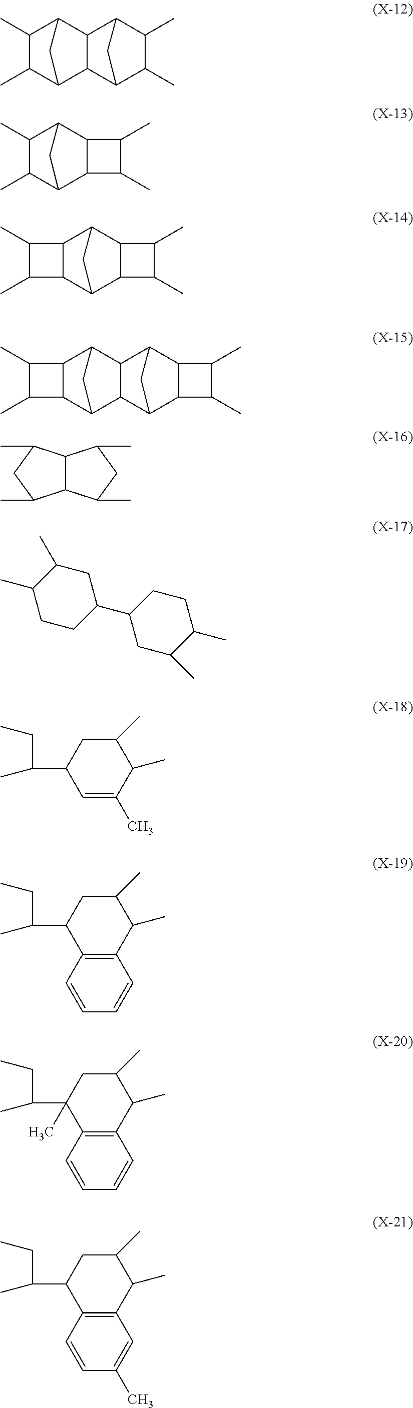

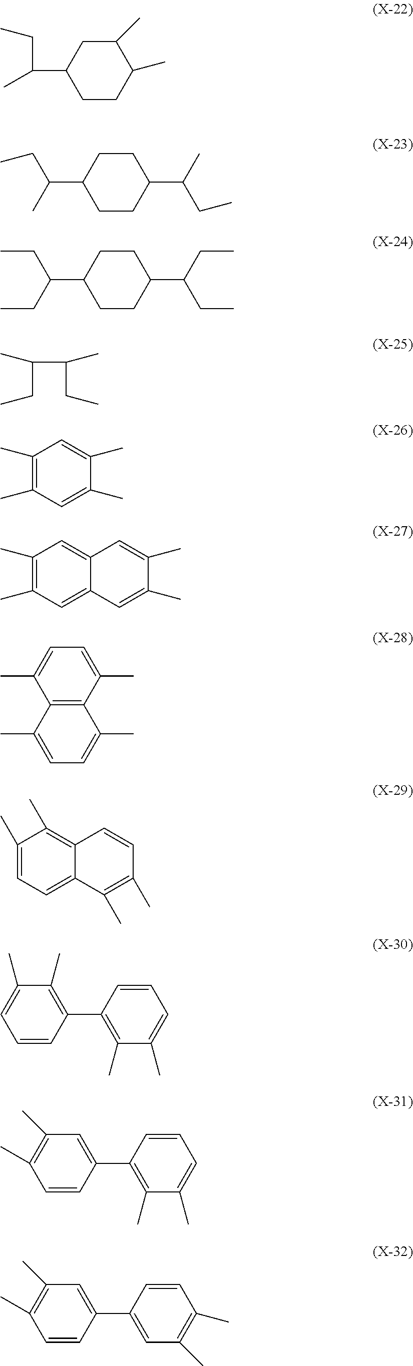

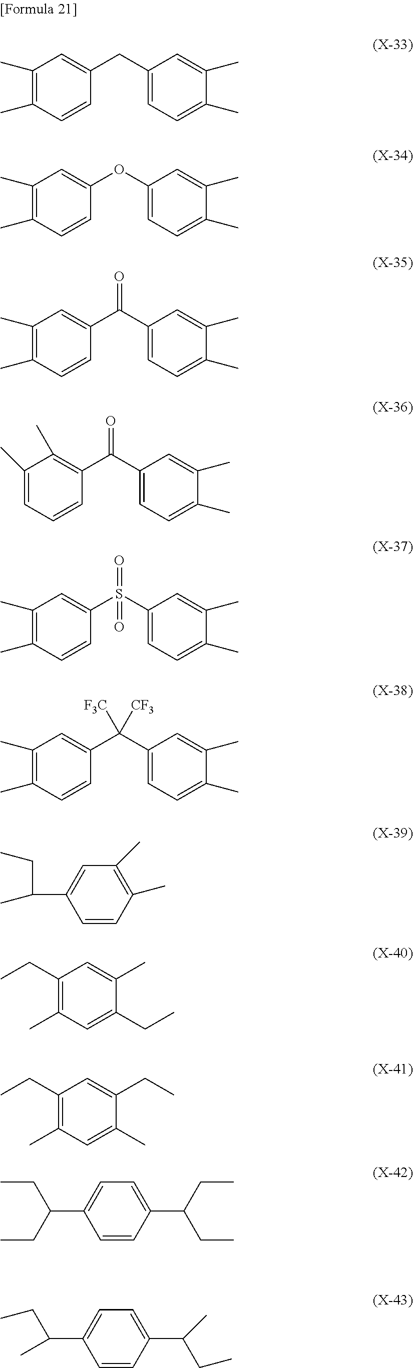

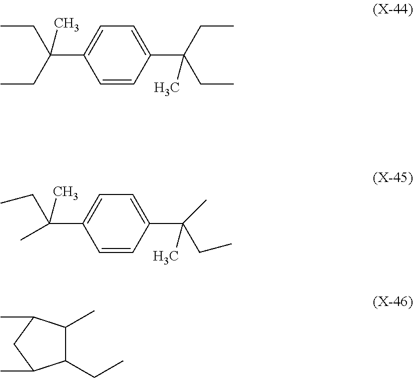

In formula (3-a), X may be the below-mentioned X₁.

In formula (1-1), Y represents a divalent organic group, and is not particularly limited, but, for example, includes a structure of Y in the diamine represented by formula (4-a) above.

Representative examples of Y in the known diamine represented by formula (4-a) are shown below, but the present invention is not limited to these examples. Further, the polyimide precursor represented by formula (1-1) may be a copolymer in which Y comprises two or more different structures.

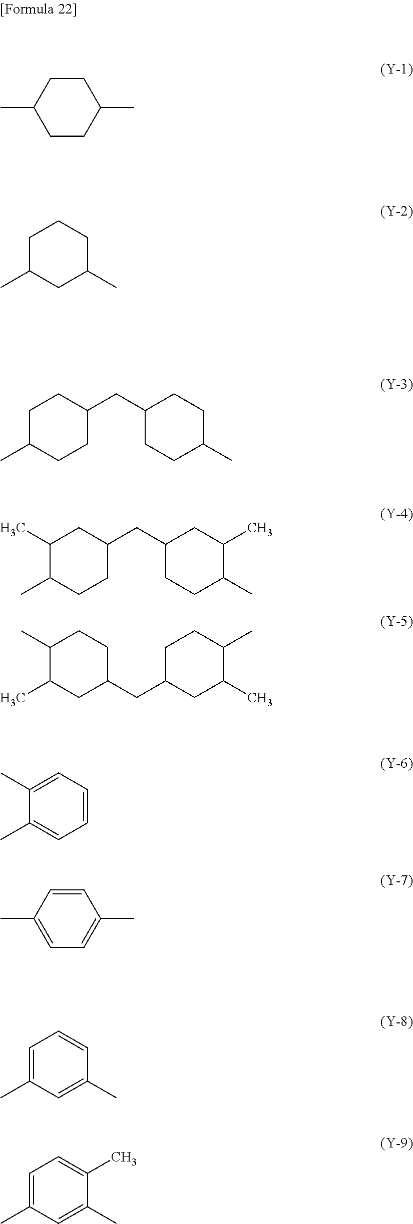

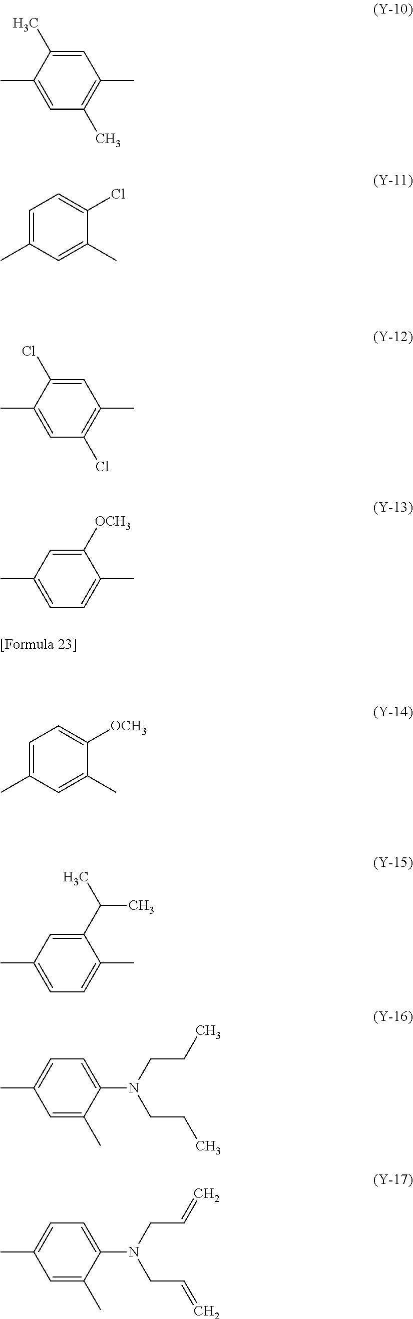

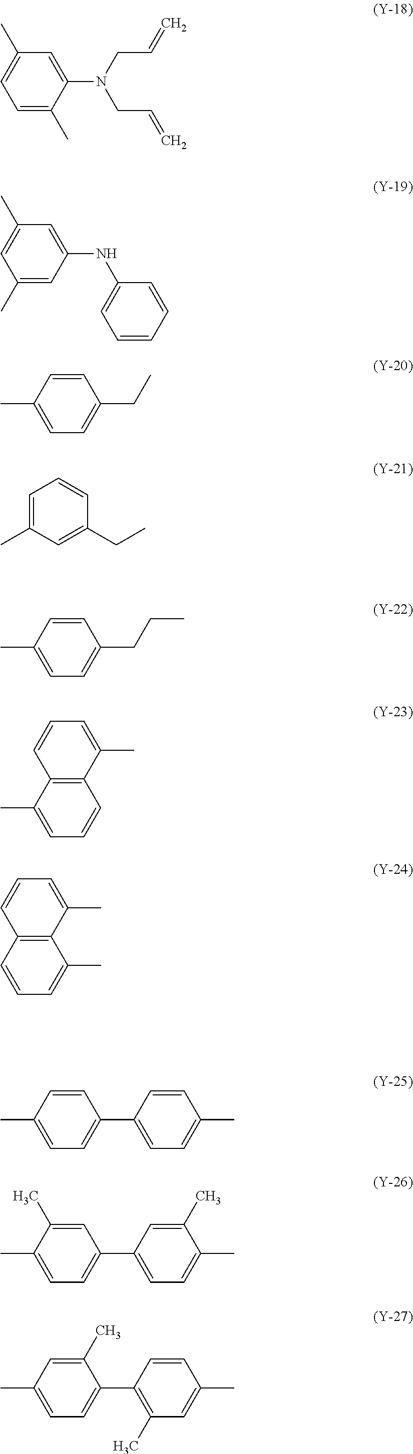

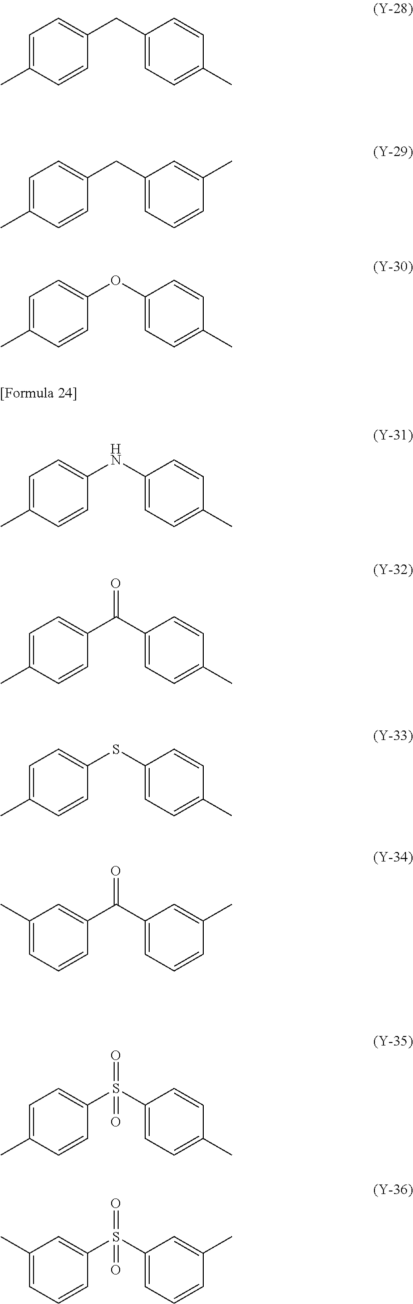

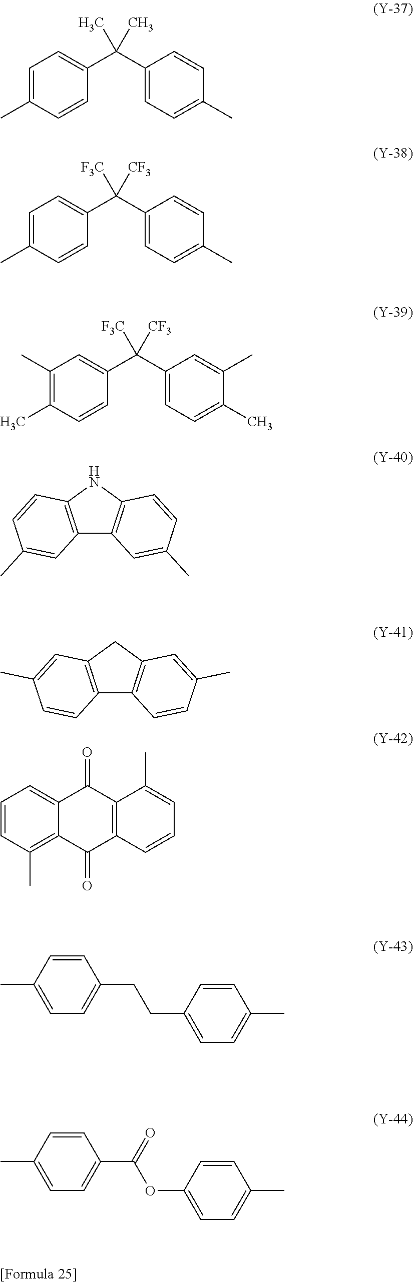

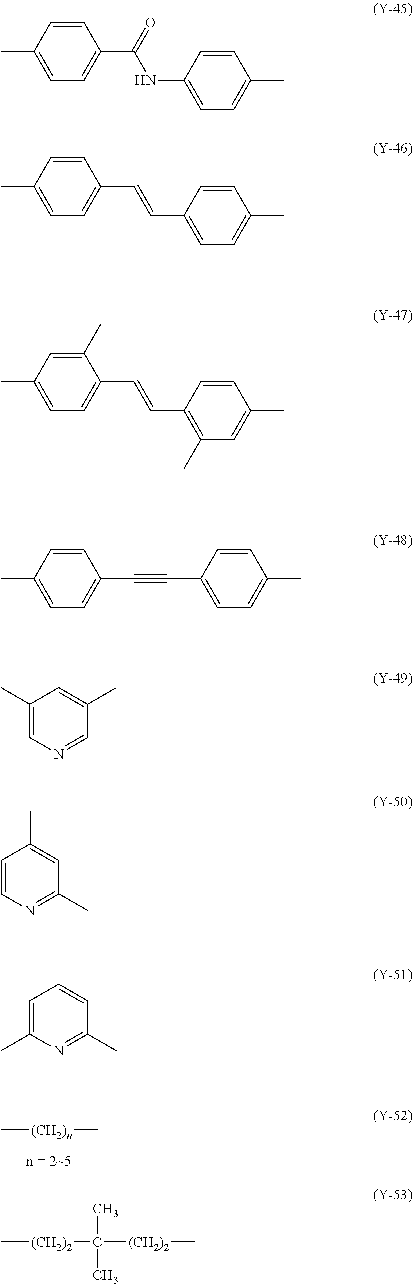

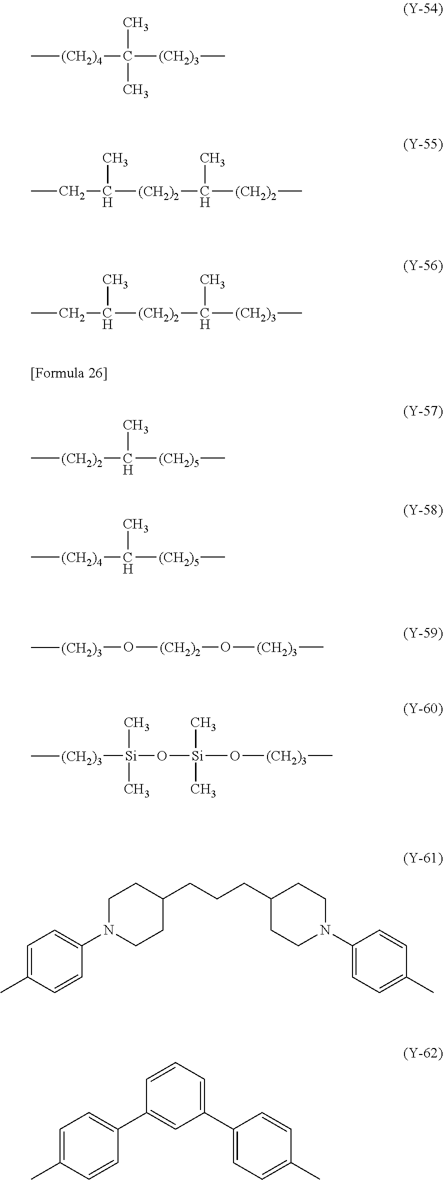

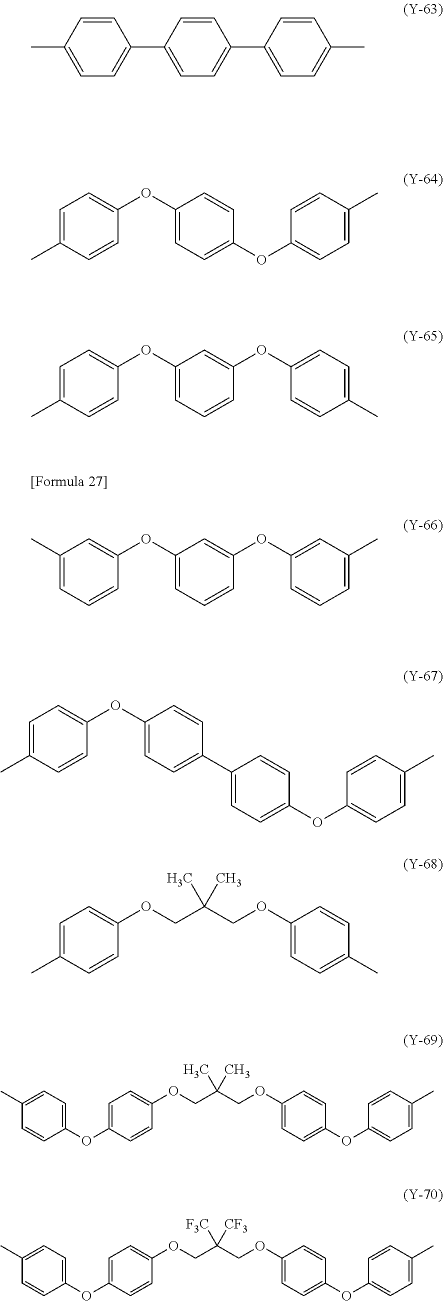

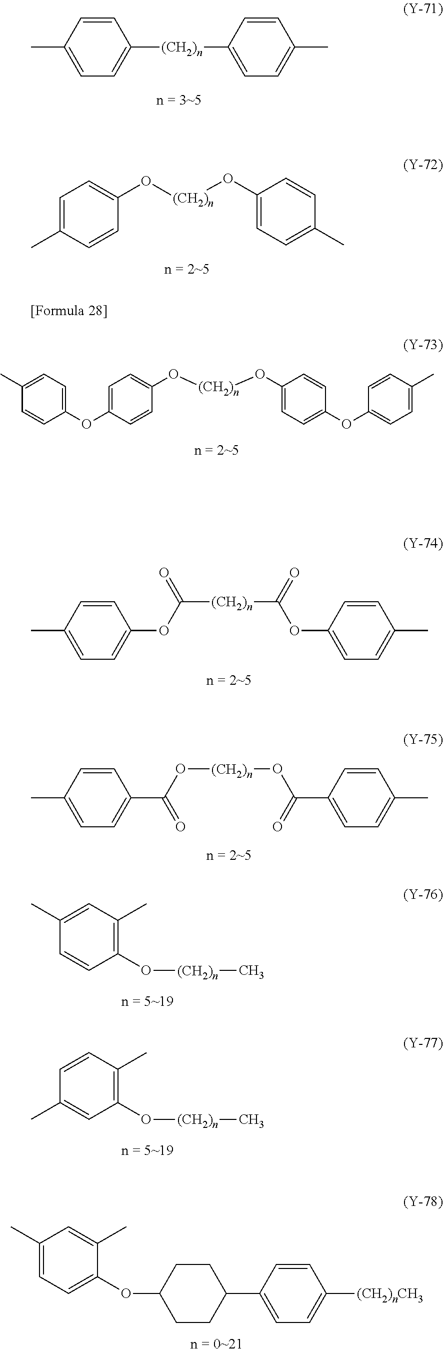

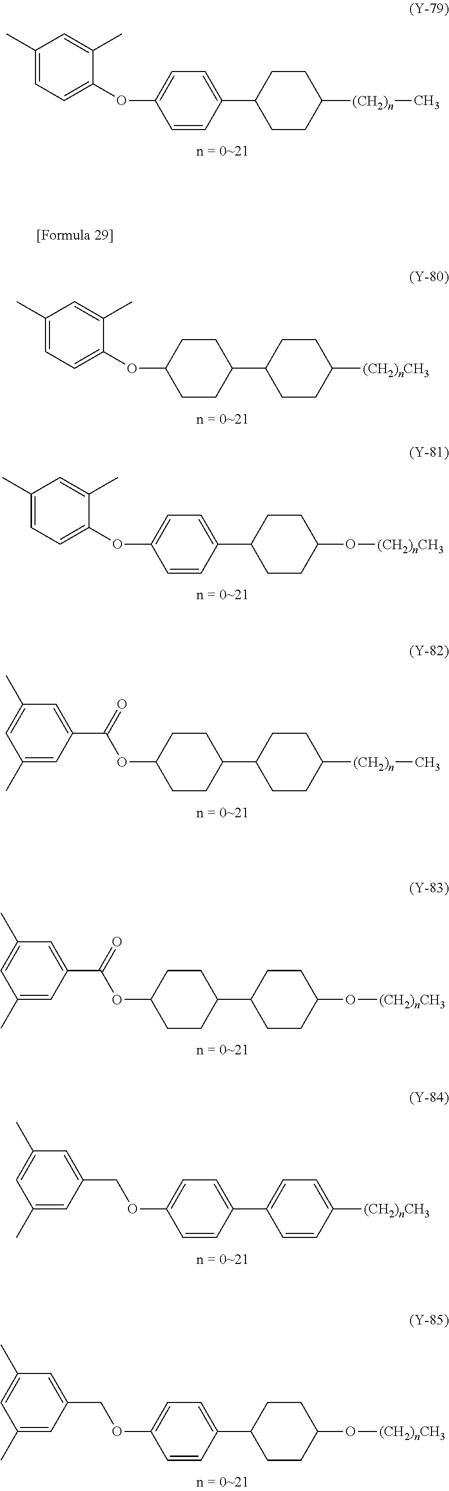

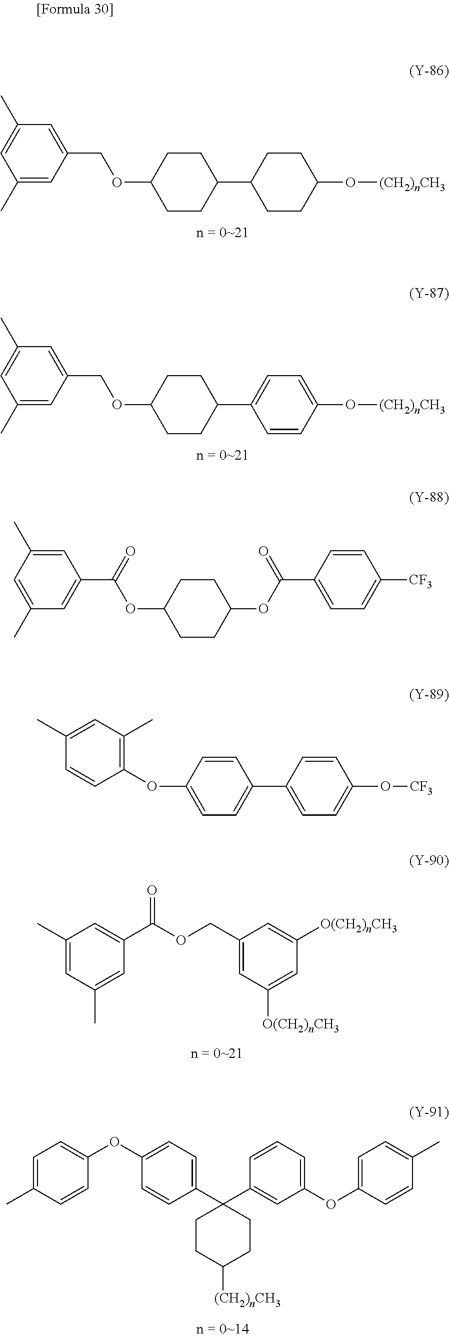

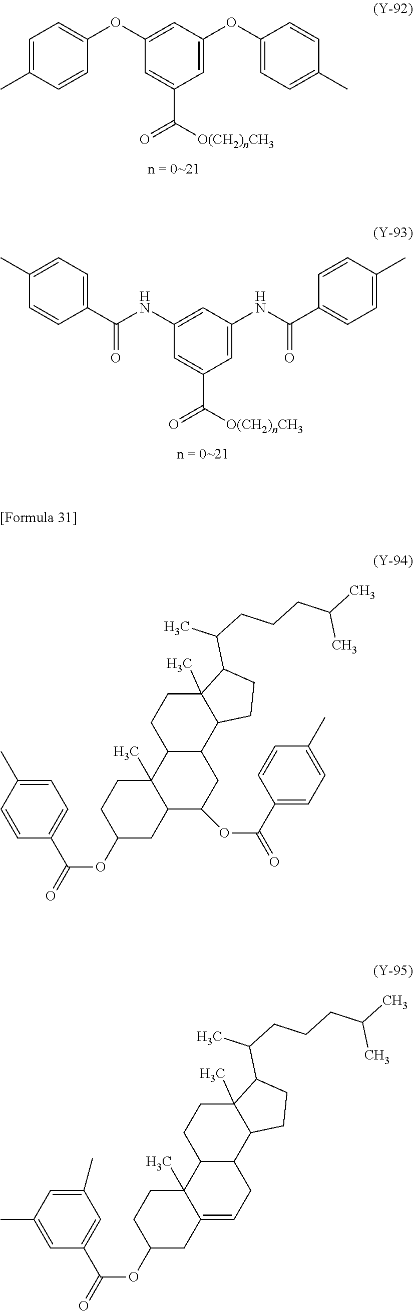

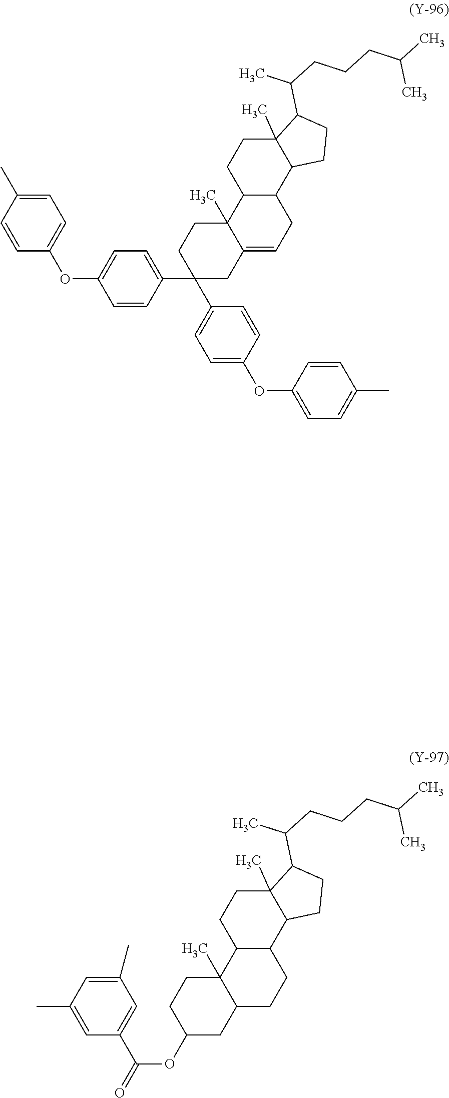

In formula (4-a), Y may be the below-mentioned Y₁.

[Synthesis of a Polyamic Acid Ester]

The polyamic acid ester can be obtained by, for example, the known method described in JP 2010-114103 A.

The polyimide precursor in the present invention is preferably a polyamide having a structure represented by the following general formula (1):

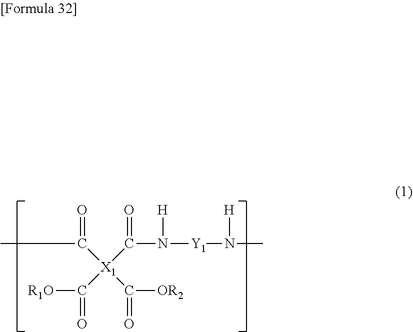

wherein X₁ is a tetravalent organic group having 6 to 40 carbon atoms, Y₁ is a divalent organic group having 6 to 40 carbon atoms, and each of R₁ and R₂ is independently a hydrogen atom or a monovalent organic group represented by the following general formula (2) or formula (3):

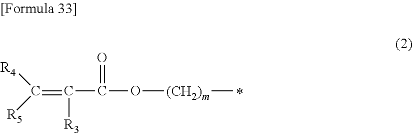

wherein each of R₃, R₄, and R₅ is independently a hydrogen atom or a monovalent organic group having 1 to 3 carbon atoms, m is an integer of 1 to 10, and * is a site bonded to the carboxylic acid present in the polyamic acid main chain of general formula (1),

[Formula 34]

R₆—* (3)
wherein R₆ is a monovalent group selected from alkyl groups having 1 to 30 carbon atoms and optionally being interrupted by an ether oxygen atom, and * is as defined above,
   wherein a proportion of the total amount of the monovalent organic group represented by general formula (2) above and the monovalent organic group represented by general formula (3) above in the total amount of R₁ and R₂ is 80% by mole or more, and a proportion of the amount of the monovalent organic group represented by general formula (3) above in the total amount of R₁ and R₂ ranges 1 to 100% by mole.

The proportion of the amount of the monovalent organic group represented by general formula (3) above in the total amount of R₁ and R₂ ranges 1 to 100% by mole, more preferably 1 to 90% by mole.

In general formula (1) above, X₁ is not limited as long as it is a tetravalent organic group having 6 to 40 carbon atoms, but, from the viewpoint of achieving both the heat resistance and the photosensitivity properties, X₁ is preferably an aromatic group in which a —COOR₁ group and a —COOR₂ group and a —CONH— group are arranged at the ortho-position, or an alicyclic aliphatic group. Further, the tetravalent organic group represented by X₁ is more preferably an organic group having 6 to 40 carbon atoms and containing an aromatic ring.

X₁ is further preferably a tetravalent organic group represented by the following formula (5) or formulae (5-1) to (5-9) (wherein * is a site bonded to another organic group).

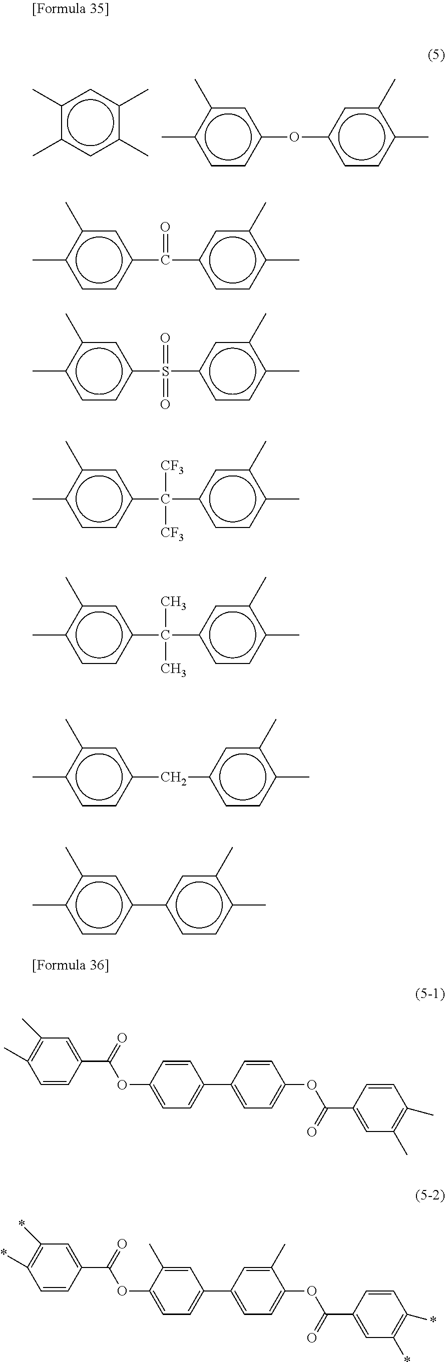

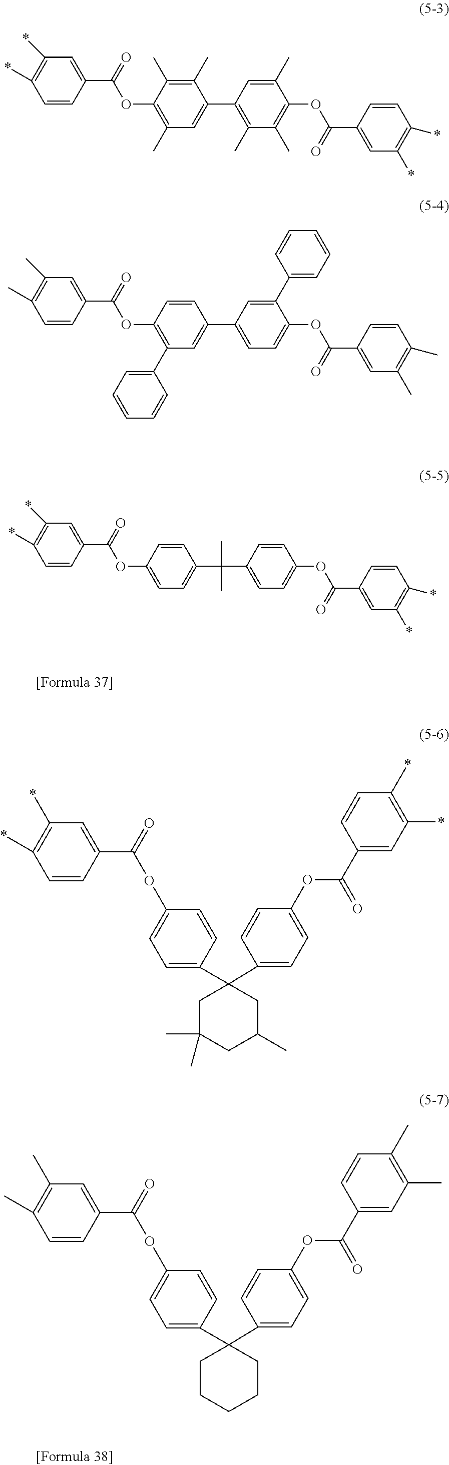

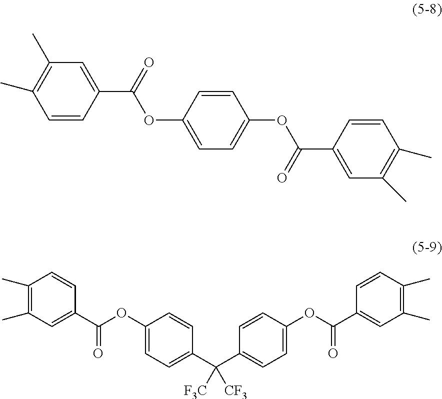

Further, X₁ may have one type of structure or a combination of two or more types of structures.

In general formula (1) above, Y₁ is not limited as long as it is a divalent organic group having 6 to 40 carbon atoms, but, from the viewpoint of achieving both the heat resistance and the photosensitivity properties, Y₁ is preferably a cyclic organic group having 1 to 4 optionally substituted aromatic rings or aliphatic rings, or an aliphatic group or siloxane group having no cyclic structure. Y₁ is more preferably a structure represented by the following general formula (6), general formula (7), or formulae (8-1) to (8-5) (wherein * is a site bonded to another organic group).

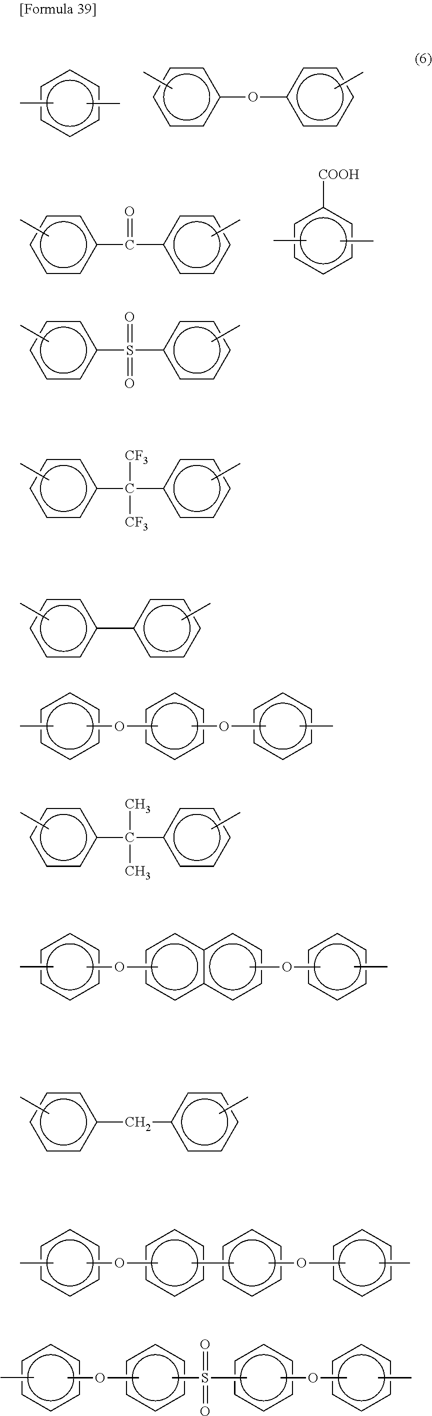

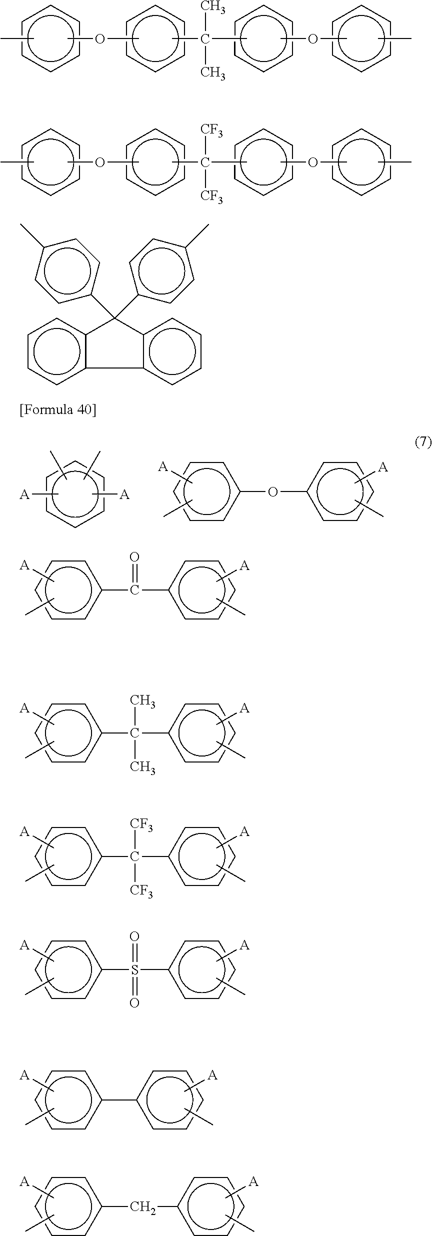

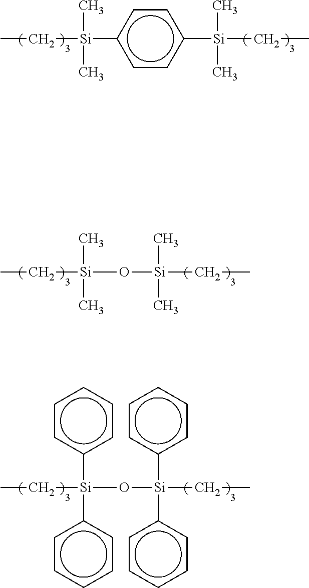

Wherein each A independently represents a methyl group (—CH₃), an ethyl group (—C₂H₅), a propyl group (—C₃H₇), or a butyl group (—C₄H₉).

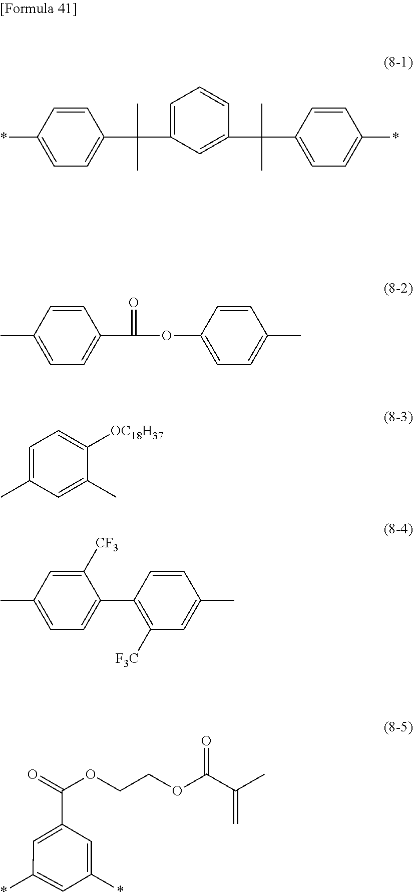

Further, Y₁ may have one type of structure or a combination of two or more types of structures.

Each of R₁ and R₂ in general formula (1) above is independently a hydrogen atom or a monovalent organic group represented by general formula (2) or (3) above.

In general formula (1) above, from the viewpoint of the photosensitivity properties and mechanical properties of the photosensitive resin composition, the proportion of the total amount of the monovalent organic group represented by general formula (2) above and the monovalent organic group represented by general formula (3) above in the total amount of R₁ and R₂ is 80% by mole or more, and the proportion of the amount of the monovalent organic group represented by general formula (3) above in the total amount of R₁ and R₂ ranges 1 to 100% by mole, preferably 1 to 90% by mole.

R₃ in general formula (2) above is not limited as long as it is a hydrogen atom or a monovalent organic group having 1 to 3 carbon atoms, but, from the viewpoint of the photosensitivity properties of the photosensitive resin composition, R₃ is preferably a hydrogen atom or a methyl group.

Each of R₄ and R₅ in general formula (2) above is not limited as long as each of R₄ and R₅ is independently a hydrogen atom or a monovalent organic group having 1 to 3 carbon atoms, but, from the viewpoint of the improvement of the imidization ratio, each of R₄ and R₅ is preferably a hydrogen atom.

m in general formula (2) above is an integer of 1 to 10, and, from the viewpoint of the improvement of the imidization ratio, m is preferably an integer of 2 to 4.

R₆ in general formula (3) above is not limited as long as it is a monovalent organic group selected from alkyl groups having 1 to 30 carbon atoms. R₆ may have any of a linear structure, a branched structure, and a cyclic structure.

Specific examples of the monovalent organic groups include linear alkyl groups, such as a methyl group, an ethyl group, a propyl group, a butyl group, a pentyl group (amyl group), a hexyl group, a heptyl group, an octyl group, a nonyl group, a decyl group, an undecyl group, a dodecyl group (lauryl group), a tridecyl group, a tetradecyl group (myristyl group), a pentadecyl group, a hexadecyl group (palmityl group), a heptadecyl group (margaryl group), an octadecyl group (stearyl group), a nonadecyl group, an icosyl group (arachyl group), a henicosyl group, a docosyl group (behenyl group), a tricosyl group, a tetracosyl group (lignoceryl group), a pentacosyl group, a hexacosyl group, and a heptacosyl group; branched alkyl groups, such as an isopropyl group, an isobutyl group, a sec-butyl group, a tert-butyl group, an isopentyl group, a neopentyl group, a tert-pentyl group, a sec-isoamyl group, an isohexyl group, a thexyl group, a 4-methylhexyl group, a 5-methylhexyl group, a 2-ethylpentyl group, a heptan-3-yl group, a heptan-4-yl group, a 4-methylhexan-2-yl group, a 3-methylhexan-3-yl group, a 2,3-dimethylpentan-2-yl group, a 2,4-dimethylpentan-2-yl group, a 4,4-dimethylpentan-2-yl group, a 6-methylheptyl group, a 2-ethylhexyl group, an octan-2-yl group, a 6-methylheptan-2-yl group, a 6-methyloctyl group, a 3,5,5-trimethylhexyl group, a nonan-4-yl group, a 2,6-dimethylheptan-3-yl group, a 3,6-dimethylheptan-3-yl group, a 3-ethylheptan-3-yl group, a 3,7-dimethyloctyl group, a 8-methylnonyl group, a 3-methylnonan-3-yl group, a 4-ethyloctan-4-yl group, a 9-methyldecyl group, an undecan-5-yl group, a 3-ethylnonan-3-yl group, a 5-ethylnonan-5-yl group, a 2,2,4,5,5-pentamethylhexan-4-yl group, a 10-methylundecyl group, a 11-methyldodecyl group, a tridecan-6-yl group, a tridecan-7-yl group, a 7-ethylundecan-2-yl group, a 3-ethylundecan-3-yl group, a 5-ethylundecan-5-yl group, a 12-methyltridecyl group, a 13-methyltetradecyl group, a pentadecan-7-yl group, a pentadecan-8-yl group, a 14-methylpentadecyl group, a 15-methylhexadecyl group, a heptadecan-8-yl group, a heptadecan-9-yl group, a 3,13-dimethylpentadecan-7-yl group, a 2,2,4,8,10,10-hexamethylundecan-5-yl group, a 16-methylheptadecyl group, a 17-methyloctadecyl group, a nonadecan-9-yl group, a nonadecan-10-yl group, a 2,6,10,14-tetramethylpentadecan-7-yl group, a 18-methylnonadecyl group, a 19-methylicosyl group, a henicosan-10-yl group, a 20-methylhenicosyl group, a 21-methyldocosyl group, a tricosan-11-yl group, a 22-methyltricosyl group, a 23-methyltetracosyl group, a pentacosan-12-yl group, a pentacosan-13-yl group, a 2,22-dimethyltricosan-11-yl group, a 3,21-dimethyltricosan-11-yl group, a 9,15-dimethyltricosan-11-yl group, a 24-methylpentacosyl group, a 25-methyihexacosyl group, and a heptacosan-13-yl group; and alicyclic alkyl groups, such as a cyclopropyl group, a cyclobutyl group, a cyclopentyl group, a cyclohexyl group, a 4-tert-butylcyclohexyl group, a 1,6-dimethylcyclohexyl group, a menthyl group, a cycloheptyl group, a cyclooctyl group, a bicyclo[2.2.1]heptan-2-yl group, a bornyl group, an isobornyl group, a 1-adamantyl group, a 2-adamantyl group, a tricyclo[5.2.1.0^{2,6}]decan-4-yl group, a tricyclo[5.2.1.0^{2,6}]decan-8-yl group, and a cyclododecyl group.

R₆ in general formula (3) above is preferably an alkyl group having 5 to 30 carbon atoms, preferably an alkyl group having 8 to 30 carbon atoms, preferably an alkyl group having 9 to 30 carbon atoms, preferably an alkyl group having 10 to 30 carbon atoms, further preferably an alkyl group having 11 to 30 carbon atoms, further preferably an alkyl group having 17 to 30 carbon atoms.

R₆ is preferably represented by the following formula (4):

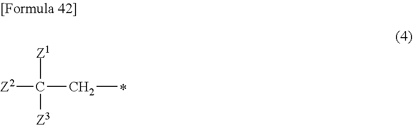

wherein Z¹ is hydrogen or an alkyl group having 1 to 14 carbon atoms,
Z² is an alkyl group having 1 to 14 carbon atoms, and
Z³ is an alkyl group having 1 to 14 carbon atoms,
wherein Z¹, Z², and Z³ are the same or different from each other, and the total number of carbon atoms of Z¹, Z², and Z³ is 4 or more.

Z¹ is preferably hydrogen.

Z¹, Z², and Z³ are preferably an alkyl group having 2 to 12 carbon atoms, preferably an alkyl group having 2 to 10 carbon atoms.

The total number of carbon atoms of Z¹, Z², and Z³ is preferably 5 or more, preferably 6 or more, preferably 10 or more, preferably 12 or more, preferably 14 or more, preferably 15 or more, preferably 16 or more.

The total number of carbon atoms of Z¹, Z², and Z³ is preferably between 6 and 20.

The upper limit of the total number of carbon atoms of Z¹, Z², and Z³ is preferably 28.

Further, R₆ may be selected from the following formulae (3-1) to (3-7) (wherein * is a site bonded to the carboxylic acid present in the polyamic acid main chain of general formula (1)).

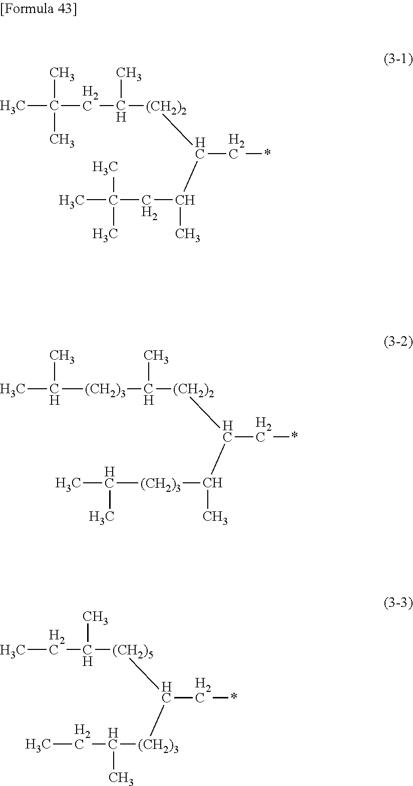

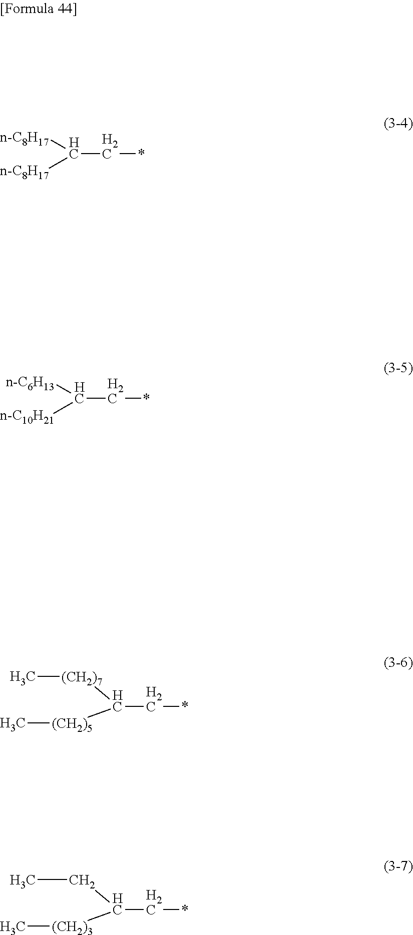

R₆ may be selected from formulae (3-1) to (3-7) above.

Further, R₆ in general formula (3) above may be a monovalent organic group selected from alkyl groups having 1 to 30 carbon atoms and being interrupted by an ether oxygen atom.

Specific examples of alkyl groups having 1 to 30 carbon atoms and being interrupted by an ether oxygen atom include alkyl groups having 1 to 30 carbon atoms, part of the carbon atoms of which is replaced by an ether oxygen atom.

Specific examples of preferred alkyl groups having 1 to 30 carbon atoms and being interrupted by an ether oxygen atom include groups represented by the following formula:

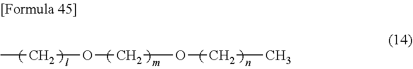

wherein 1≥1, m≥1, and 1+m+n is an integer of 1 to 7.

Specific preferred examples are as shown below:

—CH₂—O—CH₂—CH₂—O—CH₃,
—CH₂—O—CH₂—CH₂—O—C₂H₅,
—CH₂—O—CH₂—CH₂—O—C₃H₇,
—CH₂—O—CH₂—CH₂—O—C₄H₉,
—CH₂—O—CH₂—CH₂—O—C₅H₁₁,
—CH₂—CH₂—O—CH₂—O—CH₃,
—CH₂—O—CH₂—CH₂—O—CH₂—CH₂—O—CH₃,
—CH₂—CH₂—O—CH₂—CH₂—O—CH₃,
—CH₂—CH₂—CH₂—O—CH₂—CH₂—O—CH₃,
—CH₂—CH₂—CH₂—CH₂—O—CH₂—CH₂—O—CH₃, and
—CH₂—CH₂—CH₂—CH₂—CH₂—O—CH₂—CH₂—O—CH₃.

Most preferred R₆ is —CH₂—O—CH₂—CH₂—O—CH₂—CH₂—O—CH₃.

R₆ may be one type of group or a combination of two or more groups selected from the above groups, but is preferably selected from the above-mentioned alkyl groups having 1 to 30 carbon atoms, more preferably contains any one of formulae (3-1) to (3-6) above.

Polyimide precursor (A) is converted to a polyimide by a heating cyclization treatment.

[Method for Preparing Polyimide Precursor (A)]

The polyimide precursor represented by general formula (1) above in the present embodiment is obtained by, for example, reacting a tetracarboxylic dianhydride containing the above-mentioned tetravalent organic group X₁ having 6 to 40 carbon atoms, (a-1 an alcohol having a hydroxyl group bonded to a monovalent organic group represented by general formula (2) above, and (b-1) an alcohol having a hydroxyl group bonded to a monovalent organic group represented by general formula (3) above with each other to prepare a partially esterified tetracarboxylic acid (hereinafter, sometimes referred to as “acid/ester compound”), and subsequently subjecting the acid/ester compound and a diamine containing the above-mentioned divalent organic group Y₁ having 6 to 40 carbon atoms to polycondensation.

(Preparation of an Acid/Ester Compound)

In the present embodiment, examples of the tetracarboxylic dianhydrides containing a tetravalent organic group X₁ having 6 to 40 carbon atoms include pyromellitic anhydride, diphenyl ether 3,3′,4,4′-tetracarboxylic dianhydride (=4,4′-oxydiphthalic dianhydride), benzophenone-3,3′,4,4′-tetracarboxylic dianhydride, biphenyl-3,3′,4,4′-tetracarboxylic dianhydride, diphenyl sulfone 3,3′,4,4′-tetracarboxylic dianhydride, diphenylmethane-3,3′,4,4′-tetracarboxylic dianhydride, 2,2-bis(3,4-phthalic anhydride)propane, and 2,2-bis(3,4-phthalic anhydride)-1,1,1,3,3,3-hexafluoropropane.

Further, examples include tetracarboxylic dianhydrides represented by the following formulae (5-1-a) to (5-9-a).

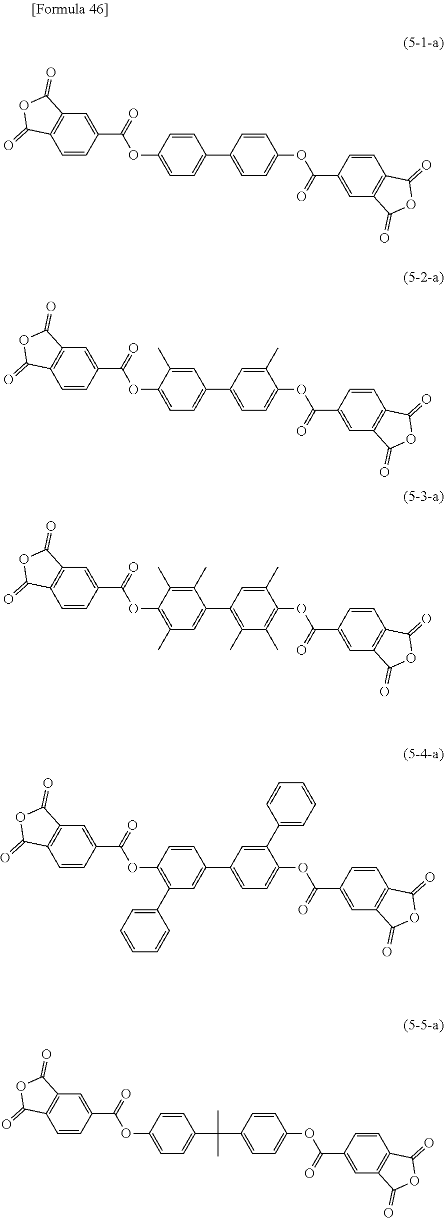 [SMILES: O=C(Oc1ccc(-c2ccc(OC(=O)c3ccc4c(c3)C(=O)OC4=O)cc2)cc1)c1ccc2c(c1)C(=O)OC2=O ; Cc1cc(-c2ccc(OC(=O)c3ccc4c(c3)C(=O)OC4=O)c(C)c2)ccc1OC(=O)c1ccc2c(c1)C(=O)OC2=O ; Cc1cc(-c2cc(C)c(OC(=O)c3ccc4c(c3)C(=O)OC4=O)c(C)c2C)c(C)c(C)c1OC(=O)c1ccc2c(c1)C(=O)OC2=O ; O=C(Oc1ccc(-c2ccc(OC(=O)c3ccc4c(c3)C(=O)OC4=O)c(-c3ccccc3)c2)cc1-c1ccccc1)c1ccc2c(c1)C(=O)OC2=O ; CC(C)(c1ccc(OC(=O)c2ccc3c(c2)C(=O)OC3=O)cc1)c1ccc(OC(=O)c2ccc3c(c2)C(=O)OC3=O)cc1]

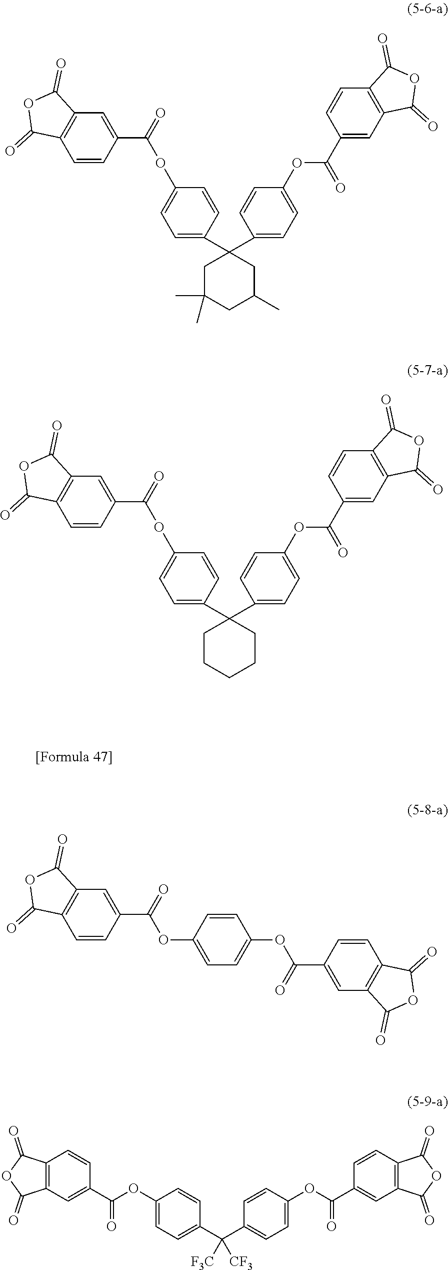 [SMILES: CC1CC(C)(C)CC(c2ccc(OC(=O)c3ccc4c(c3)C(=O)OC4=O)cc2)(c2ccc(OC(=O)c3ccc4c(c3)C(=O)OC4=O)cc2)C1 ; O=C(Oc1ccc(C2(c3ccc(OC(=O)c4ccc5c(c4)C(=O)OC5=O)cc3)CCCCC2)cc1)c1ccc2c(c1)C(=O)OC2=O ; O=C(Oc1ccc(OC(=O)c2ccc3c(c2)C(=O)OC3=O)cc1)c1ccc2c(c1)C(=O)OC2=O ; O=C(Oc1ccc(C(c2ccc(OC(=O)c3ccc4c(c3)C(=O)OC4=O)cc2)(C(F)(F)F)C(F)(F)F)cc1)c1ccc2c(c1)C(=O)OC2=O]

These may be used each alone or in combination.

In the present embodiment, examples of alcohols (a-1) having a structure represented by general formula (2) above include 2-acryloyloxyethyl alcohol, 1-acryloyloxy-3-propyl alcohol, methylol vinyl ketone, 2-hydroxyethyl vinyl ketone, 2-hydroxy-3-methoxypropyl acrylate, 2-hydroxy-3-butoxypropyl acrylate, 2-hydroxy-3-butoxypropyl acrylate, 2-methacryloyloxyethyl alcohol, 1-methacryloyloxy-3-propyl alcohol, 2-hydroxy-3-methoxypropyl methacrylate, 2-hydroxy-3-butoxypropyl methacrylate, 2-hydroxy-3-butoxypropyl methacrylate, and 2-hydroxyethyl methacrylate.

Examples of aliphatic alcohols (b-1) having 1 to 30 carbon atoms and being represented by general formula (3) above include alcohols having the above-mentioned alkyl group having 1 to 30 carbon atoms and optionally being interrupted by an ether oxygen atom, wherein a hydrogen atom of the alkyl group is replaced by a hydroxyl group.

Further, alcohols having structures of formulae (3-1-a) to (3-7-a) below may be used.

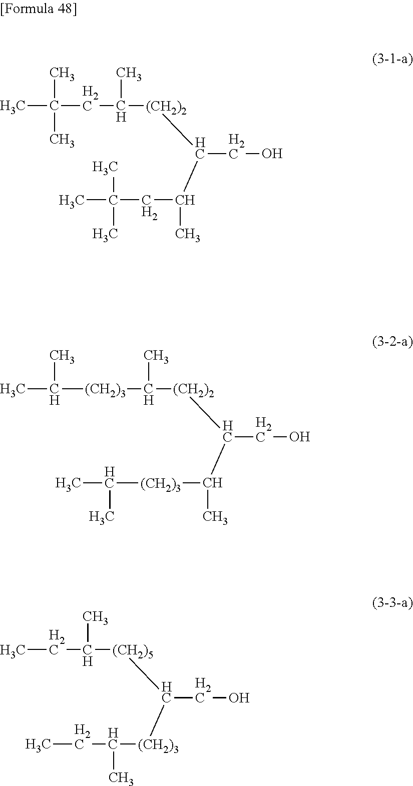

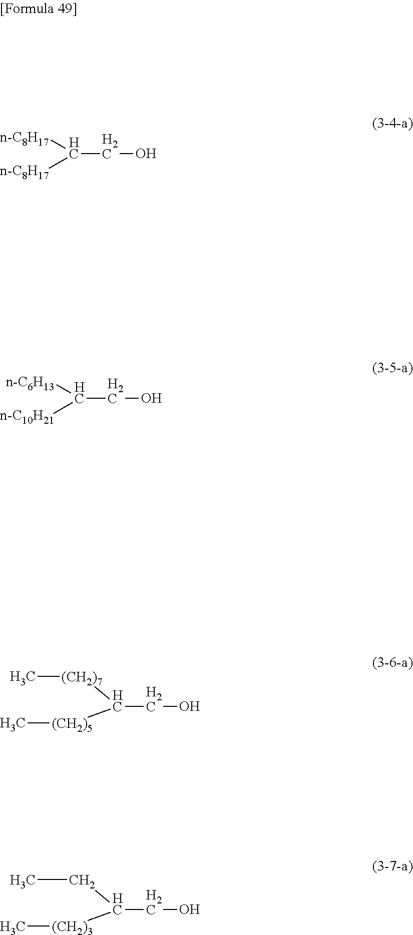

The following commercially available products may be used: an alcohol having a structure of formula (3-1): FINEOXOCOL (registered trademark) 180 (manufactured by Nissan Chemical Corporation); an alcohol having a structure of formula (3-2): FINEOXOCOL (registered trademark) 2000 (manufactured by Nissan Chemical Corporation); an alcohol having a structure of formula (3-3): FINEOXOCOL (registered trademark) 180N (manufactured by Nissan Chemical Corporation); an alcohol having a structure of formula (3-4) or (3-5): FINEOXOCOL (registered trademark) 180T (manufactured by Nissan Chemical Corporation); and an alcohol having a structure of formula (3-6): FINEOXOCOL (registered trademark) 1600K (manufactured by Nissan Chemical Corporation).

For example, triethylene glycol monomethyl ether may be used.

With respect to alcohol (b) having a hydroxyl group bonded to a monovalent organic group represented by general formula (3) above, it is preferred that alcohols having structures of formulae (3-1-a) to (3-7-a) above are used.

In the resin composition for an insulating film, the content of the total of the above-mentioned component (a-1) and component (b-1) in the total of R₁ and R₂ in general formula (1) is preferably 80% by mole or more, and, for achieving a low permittivity and a low dielectric loss tangent, the content of component (b-1) in the total of R₁ and R₂ ranges preferably 1 to 100% by mole, more preferably 1 to 90% by mole.

The above-mentioned tetracarboxylic dianhydride and the above-mentioned alcohols are stirred, dissolved, and mixed in the presence of a basic catalyst, such as pyridine, in a reaction solvent at a reaction temperature of 0 to 100° C. for 10 to 40 hours to allow a half-esterification reaction of the acid dianhydride to proceed, to obtain a desired acid/ester compound.

With respect to the reaction solvent, preferred is a solvent capable of dissolving therein the acid/ester compound and the polyimide precursor which is a polycondensation product of the acid/ester compound and the diamine, and examples of such solvents include N-methyl-2-pyrrolidone, N,N-dimethylacetamide, N,N-dimethylformamide, dimethyl sulfoxide, tetramethylurea, gamma-butyrolactone, ketones, esters, lactones, ethers, halogenated hydrocarbons, hydrocarbons, acetone, methyl ethyl ketone, methyl isobutyl ketone, cyclohexanone, methyl acetate, ethyl acetate, butyl acetate, diethyl oxalate, ethylene glycol dimethyl ether, diethylene glycol dimethyl ether, tetrahydrofuran, dichloromethane, 1,2-dichloroethane, 1,4-dichlorobutane, chlorobenzene, o-dichlorobenzene, hexane, heptane, benzene, toluene, and xylene. These may be used each alone or in combination if necessary.

(Preparation of a Polyimide Precursor)

A known dehydration condensing agent, for example, dicyclohexylcarbodiimide, 1-ethoxycarbonyl-2-ethoxy-1,2-dihydroquinoline, 1,1-carbonyldioxy-di-1,2,3-benzotriazole, or N,N′-disuccinimidyl carbonate is added to and mixed into the above-mentioned acid/ester compound (which is typically in the form of a solution in the reaction solvent) while cooling in an ice bath to convert the acid/ester compound to a polyacid anhydride, and then a solution or dispersion separately prepared by dissolving or dispersing a diamine containing divalent organic group Y₁ having 6 to 40 carbon atoms in a solvent is dropwise added to the resultant reaction mixture to carry out polycondensation, to obtain a polyimide precursor which can be used in the embodiment.

Examples of the diamines containing a divalent organic group Y₁ having 6 to 40 carbon atoms include p-phenylenediamine, m-phenylenediamine, 4,4-diaminodiphenyl ether, 3,4′-diaminodiphenyl ether, 3,3′-diaminodiphenyl ether, 4,4′-diaminodiphenyl sulfide, 3,4′-diaminodiphenyl sulfide, 3,3′-diaminodiphenyl sulfide, 4,4′-diaminodiphenyl sulfone, 3,4′-diaminodiphenyl sulfone, 3,3′-diaminodiphenyl sulfone, 4,4′-diaminobiphenyl, 3,4′-diaminobiphenyl, 3,3′-diaminobiphenyl, 4,4′-diaminobenzophenone, 3,4′-diaminobenzophenone, 3,3′-diaminobenzophenone, 4,4′-diaminodiphenylmethane, 3,4′-diaminodiphenylmethane, 3,3′-diaminodiphenylmethane, 1,4-bis(4-aminophenoxy)benzene, 1,3-bis(4-aminophenoxy)benzene, 1,3-bis(3-aminophenoxy)benzene, bis[4-(4-aminophenoxy)phenyl] sulfone, bis[4-(3-aminophenoxy)phenyl] sulfone, 4,4-bis(4-aminophenoxy)biphenyl, 4,4-bis(3-aminophenoxy)biphenyl, bis[4-(4-aminophenoxy)phenyl] ether, bis[4-(3-aminophenoxy)phenyl] ether, 1,4-bis(4-aminophenyl)benzene, 1,3-bis(4-aminophenyl)benzene, 9,10-bis(4-aminophenyl)anthracene, 2,2-bis(4-aminophenyl)propane, 2,2-bis(4-aminophenyl)hexafluoropropane, 2,2-bis[4-(4-aminophenoxy)phenyl]propane, 2,2-bis[4-(4-aminophenoxy)phenyl]hexafluoropropane, 1,4-bis(3-aminopropyldimethylsilyl)benzene, ortho-tolidine sulfone, 9,9-bis(4-aminophenyl)fluorene, and these diamines having part of hydrogen atoms on their benzene ring replaced by, e.g., a methyl group, an ethyl group, a hydroxymethyl group, a hydroxyethyl group, or a halogen, such as 3,3′-dimethyl-4,4′-diaminobiphenyl, 2,2′-dimethyl-4,4′-diaminobiphenyl, 3,3′-dimethyl-4,4′-diaminodiphenylmethane, 2,2′-dimethyl-4,4′-diaminodiphenylmethane, 3,3′-dimethoxy-4,4′-diaminobiphenyl, and 3,3′-dichloro-4,4′-diaminobiphenyl, and mixtures thereof.

Further, examples include diamines represented by the following formulae (8-1-a) to (8-5-a).

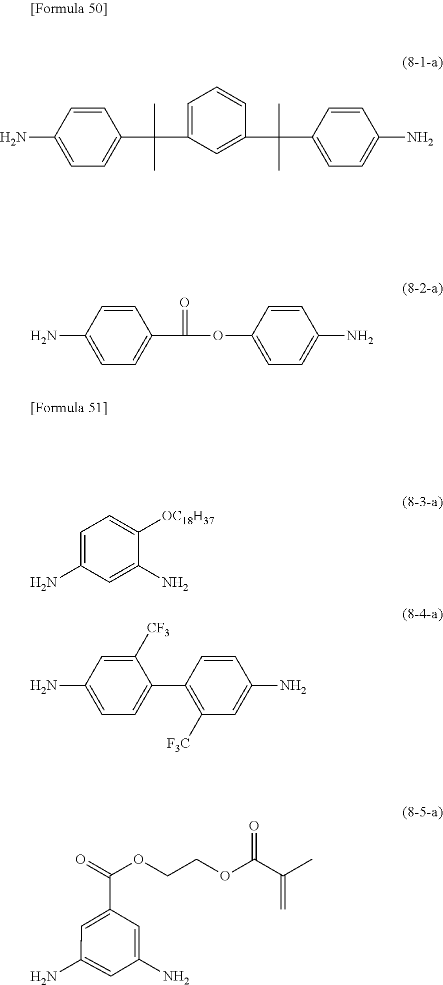

The diamine used in the present invention is not limited to these diamines.

In the embodiment, for improving the adhesion between a photosensitive resin layer formed on a substrate by applying the resin composition for an insulating film onto a substrate and a various types of substrates, a diaminosiloxane, such as 1,3-bis(3-aminopropyl)tetramethyldisiloxane or 1,3-bis(3-aminopropyl)tetraphenyldisiloxane, may be copolymerized with polyimide precursor (A) during the preparation of the polyimide precursor.

After completion of the polycondensation reaction, the water absorbing by-product of the dehydration condensing agent present in the reaction solution is removed by filtration if necessary, and then a poor solvent, such as water, an aliphatic lower alcohol, or a mixture thereof, is poured into the reaction solution to cause precipitation of the polymer component, and further the resultant polymer is purified by repeating re-dissolution and reprecipitation operations of the polymer, and subjected to vacuum drying to isolate a polyimide precursor which can be used in the embodiment. For improving the purification degree, a solution of the polymer may be passed through a column packed with an anion and/or cation exchange resin swelled with an appropriate organic solvent to remove ionic impurities.

Polyimide precursor (A) preferably has a molecular weight of 5,000 to 150,000, more preferably 7,000 to 50,000, in terms of a weight average molecular weight, as measured by gel permeation chromatography using a conversion calibration curve obtained from the standard polystyrene. When the weight average molecular weight of polyimide precursor (A) is 5,000 or more, excellent mechanical properties advantageously may be obtained. On the other hand, when the weight average molecular weight of polyimide precursor (A) is 150,000 or less, excellent dispersibility into a developer and excellent resolution performance of a relief pattern advantageously may be obtained.

[(B) Compound that Satisfies all of the Requirements (a) to (d) Shown Below](Imidization Promotor)

Component B used in the present invention is a compound which promotes thermal imidization of the above-mentioned polyimide precursor. It is necessary that the compound satisfy all the requirements (a) to (d) shown above.

Specifically, component B in the present invention has a carboxyl group (requirement (a)), and has an amino group or an imino group which is weakly basic (requirement (b)), and therefore component B is a compound which is acidic in an ordinary state. Component B has a feature such that, when component B is heated, protecting group D is eliminated and replaced by a hydrogen atom to form an amino group or imino group which is strongly basic (requirement (c)), so that component B becomes a compound having both acidic properties and basic properties. The number of strongly basic amino groups or imino groups formed due to heat is equivalent to or larger than the number of carboxyl groups (requirement (d)), and therefore component B has a further feature such that, after elimination of protecting group D, component B is collectively weakly acidic or basic.

By virtue of these features, component B in the present invention does not promote imidization of a polyamic acid ester unless protecting group D is eliminated. Therefore, the polyimide precursor composition in the present invention is advantageous in that an imidization reaction does not occur during the storage of the composition, achieving excellent storage stability.

The imidization reaction of a polyamic acid ester proceeds through a nucleophilic reaction of the nitrogen atom of an amide group to the carbonyl carbon of an ester group and the subsequent elimination of an alcohol. Thus, in the imidization reaction of a polyamic acid ester, it is considered that the reactivity of the imidization reaction is largely dependent on nucleophilicity of the nitrogen atom of an amide group and electrophilicity of the carbonyl carbon of an ester group. Component B in the present invention may improve the electrophilicity of the carbonyl carbon by the carboxyl group of component B, and may improve the nucleophilicity of the nitrogen atom by the amino group or imino group formed by deblocking of the protecting group. Accordingly, component B in the present invention has a high thermal imidization promotion effect for a polyamic acid ester which is unlikely to undergo thermal imidization.

Component Bin the present invention needs to have at least one carboxyl group, but, in view of easy handling of the compound, component B preferably has 1 to 4 carboxyl groups. On the other hand, component B needs to have at least one structure represented by formula (ND-1) or (ND-2) defined in requirement (c) above, relative to one carboxyl group, but, in view of easy handling of the compound, component B preferably has 1 to 8 structures represented by formula (ND-1 or (ND-2).

In the structure represented by formula (ND-1) or (ND-2) shown in requirement (c) above, D is a protecting group for an amino group or an imino group, which is deblocked due to heat. This means that the —ND-, —NHD, or ═ND portion contained in component B in the present invention is respectively changed by heating to —NH—, —NH₂, or ═NH. When a plurality of D's are present, the structures of D's may be different from each other.

From the viewpoint of the storage stability of the polyamic acid composition in the present invention, it is preferred that protecting group D is not eliminated at room temperature, and protecting group D is more preferably a protecting group which is eliminated by heat at 80° C. or higher, further preferably a protecting group which is eliminated by heat at 100° C. or higher. Further, from the viewpoint of the efficiency of promoting the thermal imidization of a polyamic acid ester, protecting group D is preferably a protecting group which is eliminated by heat at 300° C. or lower, more preferably a protecting group which is eliminated by heat at 250° C. or lower, further preferably a protecting group which is eliminated by heat at 200° C. or lower.

Further, the amino group represented by formula (ND-1) is required to be weakly basic by virtue of an aromatic ring or a carbonyl group bonded to the amino group before elimination of protecting group D, and to be strongly basic after elimination of protecting group D. Therefore, structure (ND-1) has a construction such that protecting group D which is to be eliminated by heat contains an aromatic ring or a carbonyl group which is bonded to an amino group so that structure (ND-1) itself is not directly bonded to an aromatic ring and a carbonyl group. Similarly, structure (ND-2) has a construction such that protecting group D which is to be eliminated by heat contains a carbon atom having an unsaturated bond which is bonded to the nitrogen atom of an imino group.

The structure of the above-mentioned protecting group D is preferably an ester group represented by the following formula (5-a):

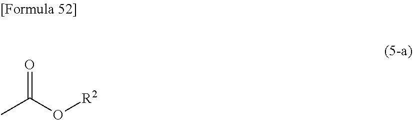

wherein R² is a hydrocarbon having 1 to 22 carbon atoms.

Specific examples of ester groups represented by formula (5-a) above include a methoxycarbonyl group, a trifluoromethoxycarbonyl group, an ethoxycarbonyl group, a n-propoxycarbonyl group, an isopropoxycarbonyl group, a n-butoxycarbonyl group, a tert-butoxycarbonyl group, a sec-butoxycarbonyl group, a n-pentyloxycarbonyl group, a n-hexyloxycarbonyl group, and a 9-fluorenylmethoxycarbonyl group. Of these, especially preferred is a tert-butoxycarbonyl group or a 9-fluorenylmethoxycarbonyl group because they are eliminated at an appropriate temperature.

Component B in the present invention is described below in more detail. The structure represented by formula (ND-1) or (ND-2) above may be expressed as a monovalent group contained in the compound.

Specific preferred examples of groups having a structure represented by formula (ND-1) or (ND-2) include groups represented by formulae (G-1) to (G-7) below. It is preferred that the compound as component B has, relative to one carboxyl group, at least one group represented by any of formulae (G-1) to (G-7).

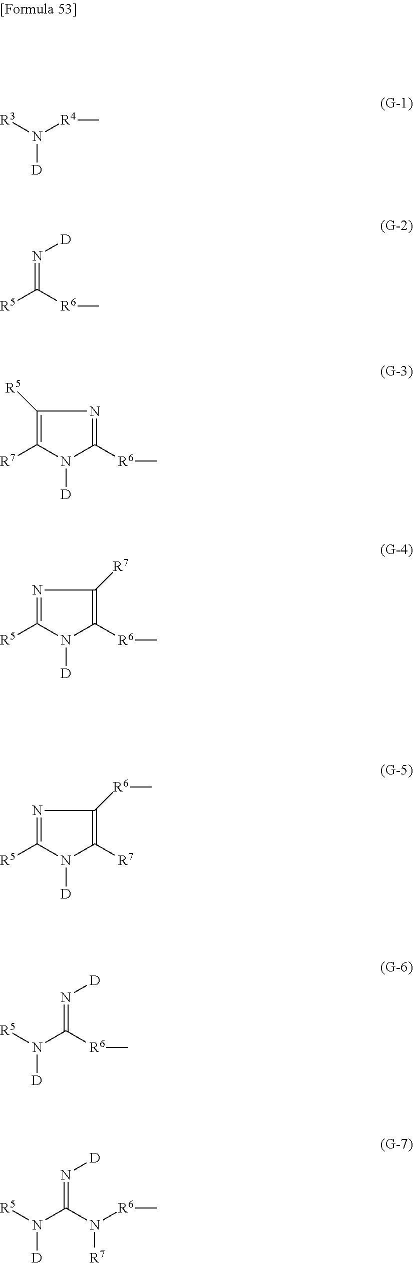

In formulae (G-1) to (G-7) above, D is a protecting group which is replaceable by a hydrogen atom upon heating, wherein when a plurality of D's are present, the structures of D's may be different from each other.

In formula (G-1), R³ is a hydrogen atom or an organic group having 1 to 30 carbon atoms, wherein the organic group is an alkyl group optionally having a substituent. R⁴ is a single bond or an organic group having 1 to 30 carbon atoms, wherein the organic group is selected from an alkylene group, an alkenylene group, an alkynylene group, and a group comprising a combination thereof, wherein each group optionally has a substituent, with the proviso that when R⁴ is a single bond, the group of formula (G-1) is not directly bonded to an aromatic ring or a carbonyl group.

In formulae (G-2) to (G-7), R⁵ and R⁷ are a hydrogen atom or an organic group having 1 to 30 carbon atoms, wherein the organic group is selected from an alkyl group, an alkenyl group, an alkynyl group, and an aryl group, wherein each group optionally has a substituent. R⁶ is a single bond or an organic group having 1 to 30 carbon atoms, wherein the organic group is selected from an alkylene group, an alkenylene group, an alkynylene group, an arylene group, and a group comprising a combination thereof, wherein each group optionally has a substituent.

R₃ to R₇ in formulae (G-1) to (G-7) may be bonded together to form a monocycle or a polycycle.

Specific examples of the alkyl groups include a methyl group, an ethyl group, a propyl group, a butyl group, a t-butyl group, a hexyl group, an octyl group, a decyl group, a cyclopentyl group, a cyclohexyl group, and a bicyclohexyl group. Examples of alkenyl groups include groups corresponding to the above-mentioned alkyl groups, one or more CH—CH structures of which are replaced by a C═C structure. More specific examples thereof include a vinyl group, an allyl group, a 1-propenyl group, an isopropenyl group, a 2-butenyl group, a 1,3-butadienyl group, a 2-pentenyl group, a 2-hexenyl group, a cyclopropenyl group, a cyclopentenyl group, and a cyclohexenyl group. Examples of alkynyl groups include groups corresponding to the above-mentioned alkyl groups, one or more CH₂—CH₂ structures of which are replaced by a C═C structure. More specific examples include an ethynyl group, a 1-propynyl group, and a 2-propynyl group. Examples of aryl groups include a phenyl group, an α-naphthyl group, a β-naphthyl group, an o-biphenylyl group, a m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the alkylene groups include structures corresponding to the above-mentioned alkyl groups, a hydrogen atom of which is removed therefrom.

More specific examples include a methylene group, a 1,1-ethylene group, a 1,2-ethylene group, a 1,2-propylene group, a 1,3-propylene group, a 1,4-butylene group, a 1,2-butylene group, a 1,2-pentylene group, a 1,2-hexylene group, a 1,2-nonylene group, a 1,2-dodecylene group, a 2,3-butylene group, a 2,4-pentylene group, a 1,2-cyclopropylene group, a 1,2-cyclobutylene group, a 1,3-cyclobutylene group, a 1,2-cyclopentylene group, a 1,2-cyclohexylene group, a 1,2-cyclononylene group, and a 1,2-cyclododecylene. Examples of alkenylene groups include structures corresponding to the above-mentioned alkenyl groups, a hydrogen atom of which is removed therefrom. More specific examples include a 1,1-ethenylene group, a 1,2-ethenylene group, a 1,2-ethenylenemethylene group, a 1-methyl-1,2-ethenylene group, a 1,2-ethenylene-1,1-ethylene group, a 1,2-ethenylene-1,2-ethylene group, a 1,2-ethenylene-1,2-propylene group, a 1,2-ethenylene-1,3-propylene group, a 1,2-ethenylene-1,4-butylene group, a 1,2-ethenylene-1,2-butylene group, a 1,2-ethenylene-1,2-heptylene group, and a 1,2-ethenylene-1,2-decylene group. Examples of alkynylene groups include structures corresponding to the above-mentioned alkynyl groups, a hydrogen atom of which is removed therefrom. More specific examples include an ethynylene group, an ethynylenemethylene group, an ethynylene-1,1-ethylene group, an ethynylene-1,2-ethylene group, an ethynylene-1,2-propylene group, an ethynylene-1,3-propylene group, an ethynylene-1,4-butylene group, an ethynylene-1,2-butylene group, an ethynylene-1,2-heptylene group, and an ethynylene-1,2-decylene group. Examples of arylene groups include structures corresponding to the above-mentioned aryl groups, a hydrogen atom of which is removed therefrom. More specific examples include a 1,2-phenylene group, a 1,3-phenylene group, a 1,4-phenylene group, a 1,2-naphthylene group, a 1,4-naphthylene group, a 1,5-naphthylene group, a 2,3-naphthylene group, a 2,6-naphthylene group, a 3-phenyl-1,2-phenylene group, and a 2,2′-diphenylene group.

The above-mentioned alkyl groups, alkenyl groups, alkynyl groups, and aryl groups may have a substituent as long as the resultant group collectively has 1 to 20 carbon atoms, and further these groups may form a cyclic structure with a substituent. The above-mentioned alkylene groups, alkenylene groups, alkynylene groups, arylene groups, and groups comprising a combination thereof may have a substituent as long as the resultant group collectively has 1 to 20 carbon atoms, and further these groups may form a cyclic structure with a substituent. The expression that the group forms a cyclic structure with a substituent means that a substituent and another one or a substituent and part of the main scaffold are bonded together to form a cyclic structure.

Examples of the substituents include a halogen group, a hydroxyl group, a thiol group, a nitro group, an organoxy group, an organothio group, an organosilyl group, an acyl group, an ester group, a thioester group, a phosphate group, an amide group, an aryl group, an alkyl group, an alkenyl group, and an alkynyl group.

Examples of the halogen group which is a substituent include a fluorine atom, a chlorine atom, a bromine atom, and an iodine atom.

Examples of the organoxy group which is a substituent include structures represented by —O—R, such as an alkoxy group, an alkenyloxy group, and an aryloxy group. Examples of R in the above structure include the above-shown alkyl groups, alkenyl groups, and aryl groups. These R's may be further substituted with the above-mentioned substituent. Specific examples of alkyloxy groups include a methoxy group, an ethoxy group, a propoxy group, a butoxy group, a pentyloxy group, a hexyloxy group, a heptyloxy group, an octyloxy group, a nonyloxy group, a decyloxy group, and a lauryloxy group.

Examples of the organothio group which is a substituent include structures represented by —S—R, such as an alkylthio group, an alkenylthio group, and an arylthio group. Examples of R in the above structure include the above-shown alkyl groups, alkenyl groups, and aryl groups. These R's may be further substituted with the above-mentioned substituent. Specific examples of alkylthio groups include a methylthio group, an ethylthio group, a propylthio group, a butylthio group, a pentylthio group, a hexylthio group, a heptylthio group, an octylthio group, a nonylthio group, a decylthio group, and a laurylthio group.

Examples of the organosilyl group which is a substituent include structures represented by —Si—(R)₃. Three quantity of R in the above structure may be the same or different, and, examples thereof include the above-shown alkyl groups and aryl groups. These R's may be further substituted with the above-mentioned substituent. Specific examples of alkylsilyl groups include a trimethylsilyl group, a triethylsilyl group, a tripropylsilyl group, a tributylsilyl group, a tripentylsilyl group, a trihexylsilyl group, a pentyldimethylsilyl group, a hexyldimethylsilyl group, an octyldimethylsilyl group, and a decyldimethylsilyl group.

Examples of the acyl group which is a substituent include structures represented by —C(O)—R. Examples of R in the above structure include the above-shown alkyl groups, alkenyl groups, and aryl groups. R may be further substituted with the above-mentioned substituent. Specific examples of acyl groups include a formyl group, an acetyl group, a propionyl group, a butyryl group, an isobutyryl group, a valeryl group, an isovaleryl group, and a benzoyl group.

Examples of the ester group which is a substituent include structures represented by —C(O)O—R or —OC(O)—R. Examples of R in the above structure include the above-shown alkyl groups, alkenyl groups, and aryl groups. R may be further substituted with the above-mentioned substituent.

Examples of the thioester group which is a substituent include structures represented by —C(S)O—R or —OC(S)—R. Examples of R in the above structure include the above-shown alkyl groups, alkenyl groups, and aryl groups. R may be further substituted with the above-mentioned substituent.

Examples of the phosphate group which is a substituent include structures represented by —OP(O)—(OR)₂. Two quantity of R in the above structure may be the same or different, and, Examples thereof include the above-shown alkyl groups and aryl groups. These R's may be further substituted with the above-mentioned substituent.

Examples of the amide group which is a substituent include structures represented by —C(O)NH₂, —C(O)NHR, —NHC(O)R, —C(O)N(R)₂, or —NRC(O)R. More than one R in the above structure may be the same or different, and, examples of R's include the above-shown alkyl groups and aryl groups. These R's may be further substituted with the above-mentioned substituent.

Examples of the aryl group which is a substituent include aryl groups which are the same as the above-mentioned examples of aryl groups. These aryl groups may be further substituted with another substituent.

Examples of the alkyl group which is a substituent include alkyl groups which are the same as the above-mentioned examples of alkyl groups. These alkyl groups may be further substituted with another substituent.

Examples of the alkenyl group which is a substituent include alkenyl groups which are the same as the above-mentioned examples of alkenyl groups. These alkenyl groups may be further substituted with another substituent.

Examples of the alkynyl group which is a substituent include alkynyl groups which are the same as the above-mentioned examples of alkynyl groups. These alkynyl groups may be further substituted with another substituent.

Specific examples of groups represented by formulae (G-1) to (G-7) are shown below, but the present invention is not limited to these examples.

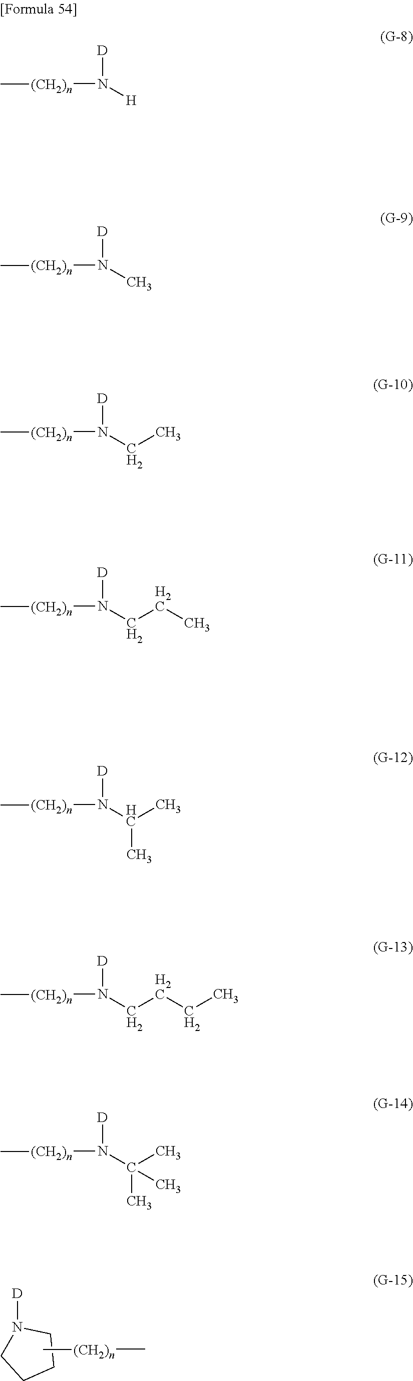

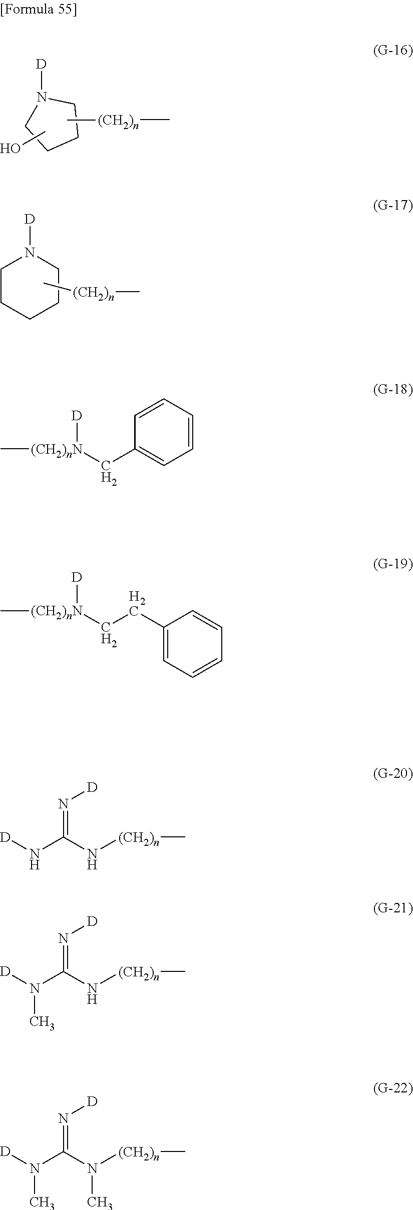

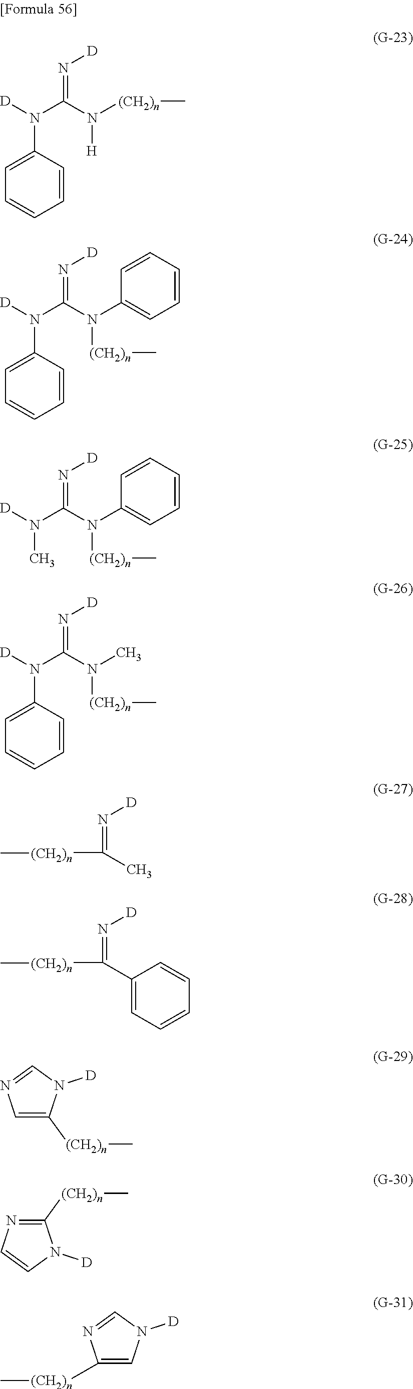

In formulae (G-8) to (G-31) above, n is an integer of 0 to 20, and D is a tert-butoxycarbonyl group or a 9-fluorenylmethoxycarbonyl group. When a plurality of D's are present in one formula, D's may be the same or different.

As a further specific preferred example of component B in the present invention include a compound represented by the following formula (6).

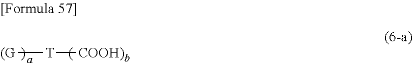

In formula (6-a) above, G represents at least one group selected from formulae (G-1) to (G-7), T represents a single bond or an organic group having 1 to 30 carbon atoms, wherein the organic group is a hydrocarbon optionally having a substituent, a is an integer of 1 to 8, and b is an integer of 1 to 4, wherein a and b satisfy the relationship: a≥b.

When a+b is 2, specific examples of hydrocarbons as T include an alkylene group, an alkenylene group, an alkynylene group, an arylene group, and a structure comprising a combination of the above groups through a single bond or a linking group represented by anyone of formulae (E-1) to (E-11) below. When a+b is more than 2, specific examples of hydrocarbons as T include structures corresponding to the above structures having removed therefrom the required number (a+b−2) of hydrogen atoms. It is noted that, in T, at least one site of formula (E-5) is bonded to an arylene group.

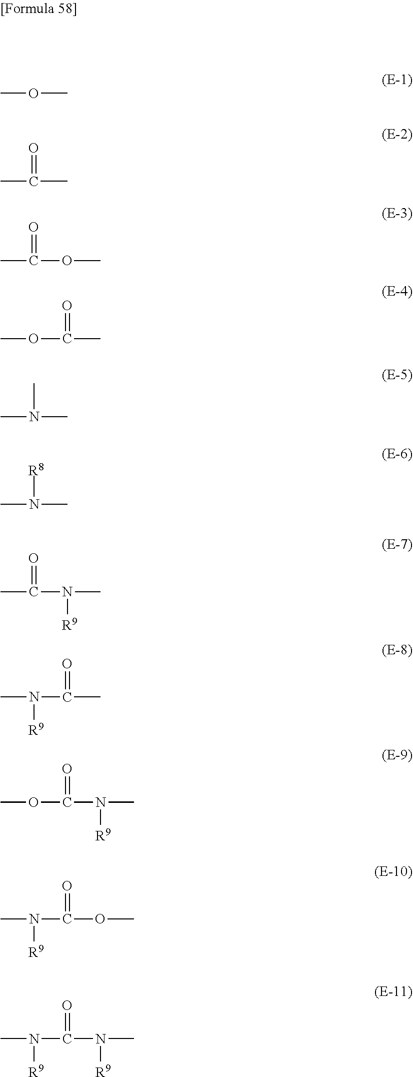

R⁸ in formula (E-6) above is a hydrogen atom, an alkyl group having 1 to 5 carbon atoms, a tert-butoxycarbonyl group, or a 9-fluorenylmethoxycarbonyl group, with the proviso that when R⁸ in T is neither a tert-butoxycarbonyl group nor a 9-fluorenylmethoxycarbonyl group, at least one site of formula (E-6) is bonded to an arylene group. Each R⁹ in formulae (E-7) to (E-11) above is independently a hydrogen atom or an alkyl group having 1 to 5 carbon atoms. Examples of alkyl groups having 1 to 5 carbon atoms include a methyl group, an ethyl group, a propyl group, a butyl group, and a t-butyl group.

Specific examples of the alkylene group, alkenylene group, alkynylene group, or arylene group constituting T include groups which are the same as the above-mentioned examples of alkylene groups and others.

The hydrocarbon as T may have a substituent. Examples of substituents include a halogen atom, a hydroxyl group, a thiol group, a phosphate group, an ester group, a thioester group, an amide group, a nitro group, an organoxy group, an organosilyl group, an organothio group, an acyl group, an alkyl group, an alkenyl group, an alkynyl group, and an aryl group, and the substituent may form a cyclic structure with a further substituent. Specific examples of the substituents include substituents which are the same as the above-mentioned examples of substituents. In addition, the substituent for the hydrocarbon as T may be a nitrogen-containing heterocycle of any one of the following structures.

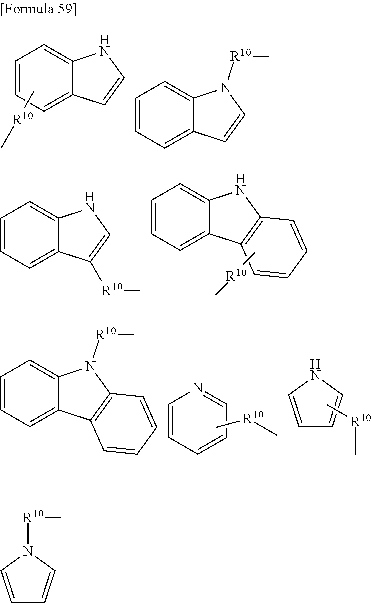

In the above structures, R¹⁰ represents a single bond or an alkylene group having 1 to 5 carbon atoms. Examples of alkylene groups having 1 to 5 carbon atoms include a methylene group, a 1,1-ethylene group, a 1,2-ethylene group, a 1,2-propylene group, a 1,3-propylene group, a 1,4-butylene group, a 1,2-butylene group, and a 1,2-pentylene group.

More preferred examples of the compounds represented by formula (6-a) above include compounds represented by the following formula (7-a) or (8-a).

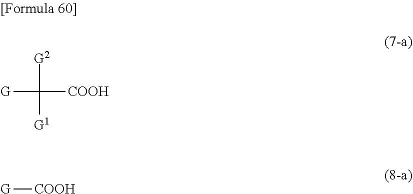

In the above formulae, G is any one of groups represented by formulae (G-1) to (G-7), and each of G¹ and G² independently represents a hydrogen atom or an organic group having 1 to 20 carbon atoms, wherein the organic group is a hydrocarbon optionally having a substituent, with the proviso that when G¹ and G² are not any of the groups of formulae (G-1) to (G-7), the total number of carbon atoms of G¹ and G² is 0 to 29.

Examples of hydrocarbons as G¹ and G² include an alkyl group, an alkenyl group, an alkynyl group, and an aryl group, and these substituents may have a substituent. Specific examples of the above alkyl groups and others include groups which are the same as the above-mentioned examples of alkyl groups and others. Further, specific examples of the substituents include substituents which are the same as the above-mentioned examples of substituents for the hydrocarbon as T in formula (6-a).

Among the compounds represented by formula (7-a) or (8-a) above, compounds represented by formula (9) or (10) below are preferred, because the carboxyl group and the basic property-generating site of the compound are present at appropriate positions such that they may simultaneously act on both the carbonyl carbon and nitrogen atom which contribute to imidization of polyamic acid ester, making it possible to more efficiently promote the imidization.

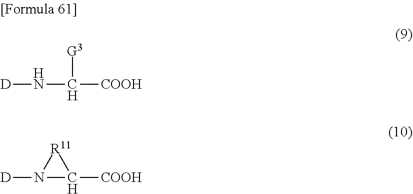

In the above formulae, D is a tert-butoxycarbonyl group or a 9-fluorenylmethoxycarbonyl group. In formula (9), G³ represents the same as G¹ in formula (7-a), and, in formula (10), R¹¹ represents an alkylene group having 1 to 5 carbon atoms and optionally having a substituent.

Examples of alkylene groups having 1 to 5 carbon atoms include a methylene group, a 1,1-ethylene group, a 1,2-ethylene group, a 1,2-propylene group, a 1,3-propylene group, a 1,4-butylene group, a 1,2-butylene group, and a 1,2-pentylene group. Further, examples of substituents include a halogen atom, a hydroxyl group, a thiol group, a phosphate group, an ester group, a thioester group, an amide group, a nitro group, an organoxy group, an organosilyl group, an organothio group, an acyl group, an alkyl group, an alkenyl group, an alkynyl group, and an aryl group. Specific examples of the substituents include substituents which are the same as the above-mentioned examples of substituents.

Specific examples of the compounds represented by formula (9) or (10) above are shown below, but the present invention is not limited to these examples.

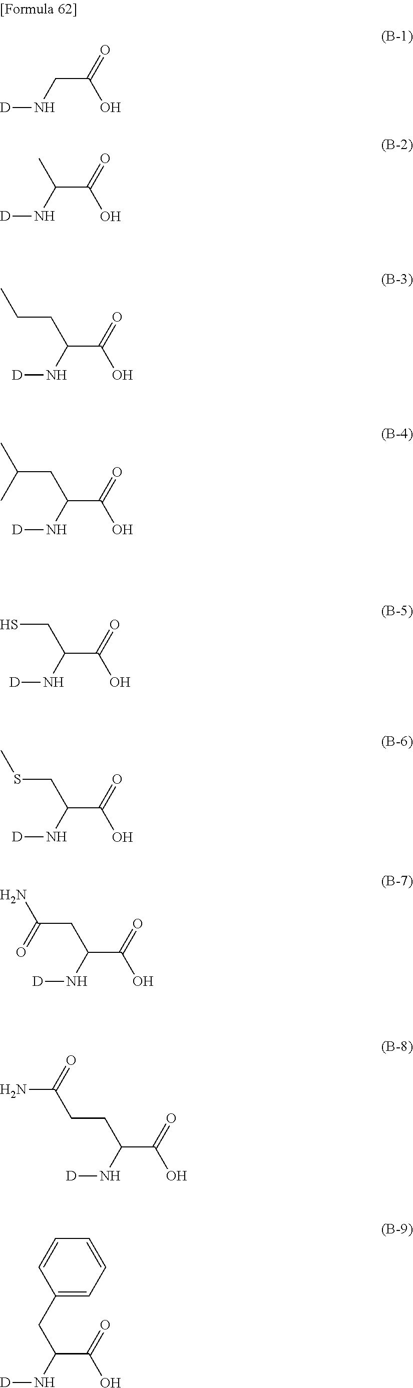

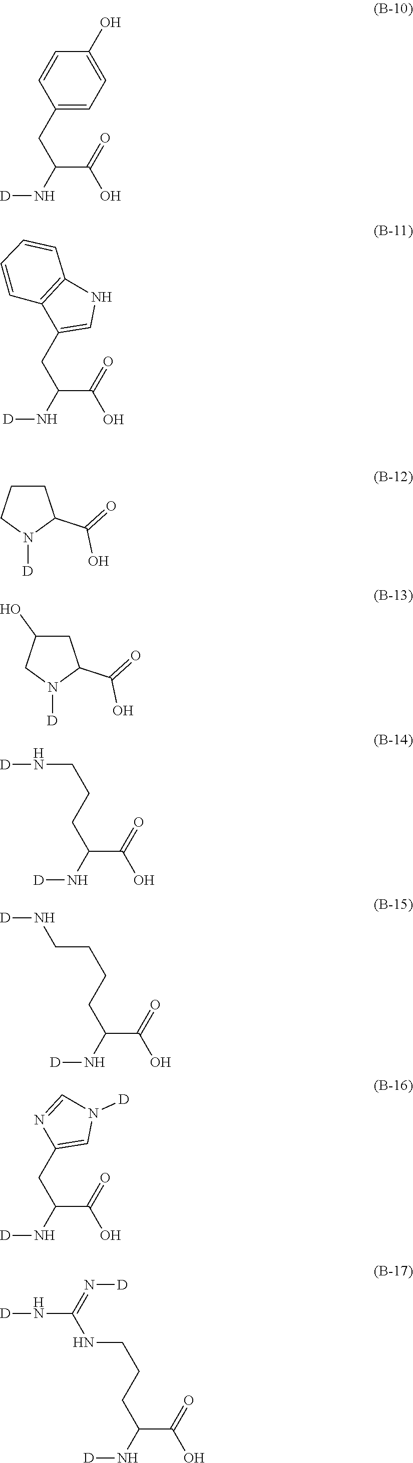

In formulae (B-1) to (B-17) above, each D is independently a tert-butoxycarbonyl group or a 9-fluorenylmethoxycarbonyl group. In formulae (B-14) to (B-17), a plurality of D's are present in each formula, and D's may be the same or different.

As the structure represented by formula (ND-1) or (ND-2) defined in requirement (c) above is increased, component B in the present invention becomes highly basic after deblocking, so that the imidization promotion effect for the polyimide precursor is further improved. Therefore, from the viewpoint of improving the thermal imidization promotion effect, component B is more preferably a compound having, relative to one carboxyl group, two or more structures represented by formula (ND-1) or (ND-2). For the same reason, with respect to the at least one group selected from formulae (G-1) to (G-7), the compound has, relative to one carboxyl group, preferably two or more groups, more preferably 2 to 4 groups. From such a point of view, of the specific examples of component (B), preferred are (B-14) to (B-17), and especially preferred is (B-17).

Abbreviations of the compounds especially preferably used are shown below.
(9-Fluorenylmethoxycarbonyl)-N-t-butoxycarbonyl-L-histidine (hereinafter, referred to simply as “Fmoc-His”)
N-α,N-ω1,N-ω2-Tri-t-butoxycarbonyl-L-arginine (hereinafter, referred to simply as “Boc-Arg”)
N-α,im-di-t-Butoxycarbonyl-L-histidine (hereinafter, referred to simply as “Boc-His”)
N-α-(9-Fluorenylmethoxycarbonyl)-N-ε-t-butoxycarbonyl-L-lysine (hereinafter, referred to simply as “Fmoc-Lys”)

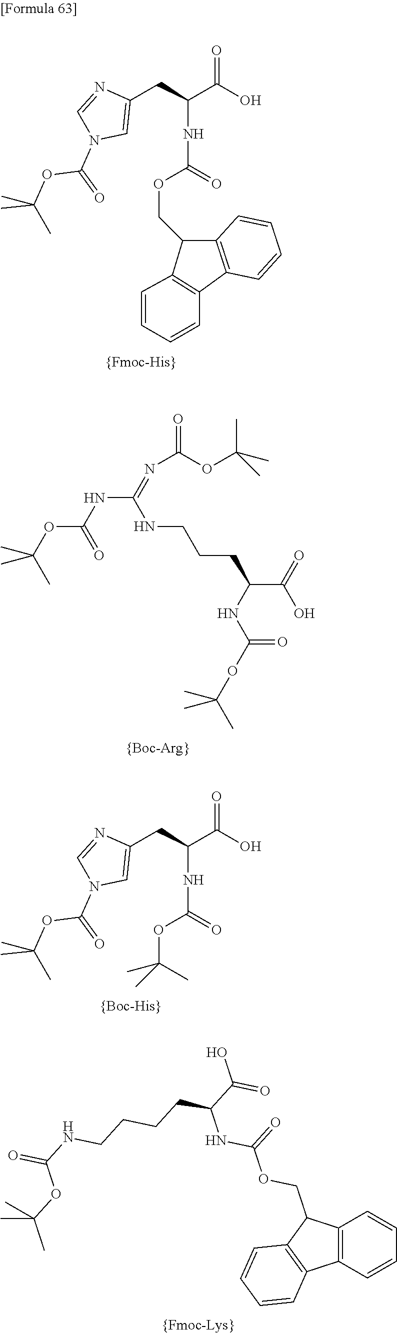 [SMILES: CC(C)(C)OC(=O)n1cnc(C[C@H](NC(=O)OCC2c3ccccc3-c3ccccc32)C(=O)O)c1 ; CC(C)(C)OC(=O)/N=C(\NCCC[C@H](NC(=O)OC(C)(C)C)C(=O)O)NC(=O)OC(C)(C)C ; CC(C)(C)OC(=O)N[C@@H](Cc1cn(C(=O)OC(C)(C)C)cn1)C(=O)O ; CC(C)(C)OC(=O)NCCCC[C@H](NC(=O)OCC1c2ccccc2-c2ccccc21)C(=O)O]

[(C) Organic Solvent]

With respect to organic solvent (C) used in the resin composition for an insulating film of the present invention, examples include N,N-dimethylformamide, N-methyl-2-pyrrolidone, N-ethyl-2-pyrrolidone, N,N-dimethylacetamide, dimethyl sulfoxide, diethylene glycol dimethyl ether, cyclopentanone, cyclohexanone, y-butyrolactone, a-acetyl-y-butyrolactone, tetramethylurea, 1,3-dimethyl-2-imidazolinone, and N-cyclohexyl-2-pyrrolidone, and these can be used each alone or in combination.

The resin composition for an insulating film of the present invention contains the above-mentioned component A, component B, and component C, and each component may contain a single species or more than one species.

With respect to the amount of component A contained, there is no particular limitation as long as component A can be dissolved in solvent component C in the presence of component B. The amount of component A contained ranges, for example, preferably 0.1 to 30% by mass, more preferably 0.5 to 20% by mass, especially preferably 1 to 40% by mass, based on the mass of the polyimide precursor composition.

The amount of component B contained is appropriately selected according to, for example, the imidization ratio of the polyimide film to be obtained, the type of component A or component B, or the baking temperature and baking time employed in the thermal imidization. That is, with respect to the amount of component B contained, there is no particular limitation as long as an effect of promoting thermal imidization of component A can be obtained. However, generally, the amount of component B contained is preferably 0.01% by mass or more, more preferably 0.05% by mass or more, further preferably 0.1% by mass or more, based on the mass of component A contained. On the other hand, from the viewpoint of minimizing the adverse effects of component B itself remaining in the film after baking on the properties of the polyimide film, the amount of component B contained is preferably 20% by mass or less, more preferably 15% by mass or less, further preferably 10% by mass or less, based on the mass of component A contained.

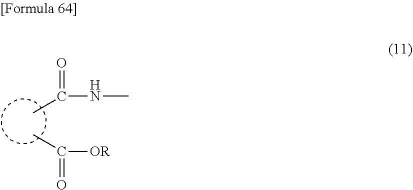

Further, the amount of component C contained ranges preferably 50 to 99.5% by mass, more preferably 75 to 99% by mass, especially preferably 50 to 95% by mass, based on the mass of the polyimide precursor composition.

[(D) Photopolymerization Initiator]

When the resin composition for an insulating film of the present invention is a negative photosensitive resin composition, the resin composition comprises a photopolymerization initiator as component (D), preferably comprises a radical photopolymerization initiator. With respect to the photopolymerization initiator, there is no particular limitation as long as it is a compound having an absorption for the light source used in photo-curing, but examples of photopolymerization initiators include organic peroxides, such as tert-butyl peroxy-iso-butyrate, 2,5-dimethyl-2,5-bis(benzoyldioxy)hexane, 1,4-bis[α-(tert-butyldioxy)-iso-propoxy]benzene, di-tert-butyl peroxide, 2,5-dimethyl-2,5-bis(tert-butyldioxy)hexene hydroperoxide, α-(iso-propylphenyl)-iso-propyl hydroperoxide, tert-butyl hydroperoxide, 1,1-bis(tert-butyldioxy)-3,3,5-trimethylcyclohexane, butyl 4,4-bis(tert-butyldioxy)valerate, cyclohexanone peroxide, 2,2′,5,5′-tetra(tert-butylperoxycarbonyl)benzophenone, 3,3′,4,4′-tetra(tert-butylperoxycarbonyl)benzophenone, 3,3′,4,4′-tetra(tert-amylperoxycarbonyl)benzophenone, 3,3′,4,4′-tetra(tert-hexylperoxycarbonyl)benzophenone, 3,3′-bis(tert-butylperoxycarbonyl)-4,4′-dicarboxybenzophenone, tert-butyl peroxybenzoate, and di-tert-butyl diperoxyisophthalate; quinones, such as 9,10-anthraquinone, 1-chloroanthraquinone, 2-chloroanthraquinone, octamethylanthraquinone, and 1,2-benzanthraquinone; benzoin derivatives, such as benzoin methyl, benzoin ethyl ether, a-methylbenzoin, and α-phenylbenzoin; alkylphenone compounds, such as 2,2-dimethoxy-1,2-diphenylethan-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-[4-{4-(2-hydroxy-2-methyl-propionyl)benzyl}-phenyl]-2-methyl-propan-1-one, phenylglyoxylic acid methyl ester, 2-methyl-1-[4-(methylthio)phenyl]-2-morpholinopropan-1-one, 2-benzyl-2-dimethylamino-1-(4-morpholinophenyl)-1-butanone, and 2-dimethylamino-2-(4-methyl-benzyl)-1-(4-morpholin-4-yl-phenyl)-butan-1-one; acylphosphine oxide compounds, such as bis(2,4,6-trimethylbenzoyl)-phenylphosphine oxide and 2,4,6-trimethylbenzoyl-diphenyl-phosphine oxide; and oxime ester compounds, such as 2-(O-benzoyloxime)-1-[4-(phenylthio)phenyl]-1,2-octanedione and 1-(O-acetyloxime)-1-[9-ethyl-6-(2-methylbenzoyl)-9H-carbazol-3-yl]ethanone.

The radical photopolymerization initiator is commercially available, and examples of commercially available products include IRGACURE [registered trademark] 651, IRGACURE 184, IRGACURE 2959, IRGACURE 127, IRGACURE 907, IRGACURE 369, IRGACURE 379EG, IRGACURE 819, IRGACURE 819DW, IRGACURE 1800, IRGACURE 1870, IRGACURE 784, IRGACURE OXE01, IRGACURE OXE02, IRGACURE OXE03, IRGACURE OXE04, IRGACURE 250, IRGACURE 1173, IRGACURE MBF, IRGACURE TPO, IRGACURE 4265, IRGACURE TPO (each of which is manufactured by BASF AG), KAYACURE [registered trademark] DETX, KAYACURE MBP, KAYACURE DMBI, KAYACURE EPA, KAYACURE OA (each of which is manufactured by Nippon Kayaku Co., Ltd.), VICURE-10, VICURE-55 (each of which is manufactured by STAUFFER Co., LTD.), ESACURE KIP150, ESACURE TZT, ESACURE 1001, ESACURE KT046, ESACURE KB1, ESACURE KL200, ESACURE KS300, ESACURE EB3, Triazine-PMS, Triazine A, Triazine B (each of which is manufactured by Nihon Siber Hegner K.K.), and Adeka Optomer N-1717, Adeka Optomer N-1414, Adeka Optomer N-1606 (each of which is manufactured by ADEKA Corporation). These radical photopolymerization initiators may be used each alone or in combination.

The amount of the photopolymerization initiator (D), preferably radical photopolymerization initiator (D) incorporated, relative to 100 parts by mass of polyimide precursor (A), ranges 0.1 to 20 parts by mass, and preferably 0.5 to 15 parts by mass from the viewpoint of the photosensitivity properties. When radical photopolymerization initiator (D) is incorporated in an amount of 0.1 part by mass or more, relative to 100 parts by mass of polyimide precursor (A), the obtained negative photosensitive resin composition has excellent photosensitivity. On the other hand, when radical photopolymerization initiator (D) is incorporated in an amount of 20 parts by mass or less, the obtained negative photosensitive resin composition exhibits excellent curing properties for a film having an increased thickness.

[(E) Crosslinkable Compound]

In the embodiment, it is preferred that the resin composition for an insulating film and/or the negative photosensitive resin composition further comprises (E) a crosslinkable compound. The crosslinkable compound may serve as a crosslinking agent in such a manner as the crosslinkable compound may induce the crosslinking of polyimide precursor (A) or the crosslinkable compound itself may form a crosslinked network, when a relief pattern formed using the resin composition for an insulating film and/or the negative photosensitive resin composition is photo-cured. Crosslinkable compound (E) is preferable, because it may further improve the heat resistance and chemical resistance of a cured film formed from the resin composition for an insulating film and/or the negative photosensitive resin composition. Examples of light sources used in the exposure for the film include a g-line, an h-line, an i-line, a ghi-line broad band, and a KrF excimer laser. The exposed dose ranges desirably 25 to 1,000 mJ/cm².

In the embodiment, for improving the resolution of the relief pattern, a monomer having a photopolymerizable unsaturated bond may be optionally incorporated into the resin composition for an insulating film and/or the negative photosensitive resin composition. As such a monomer, preferred is (a)an (meth)acrylic compound which undergoes a radical polymerization reaction due to a photopolymerization initiator, and there is no particular limitation, but examples of monomers include ethylene glycol or polyethylene glycol mono- or di-diacrylate or methacrylate, such as diethylene glycol dimethacrylate and tetraethylene glycol dimethacrylate, propylene glycol or polypropylene glycol mono- or di-acrylate or methacrylate, glycerol mono-, di-, or tri-acrylate or methacrylate, cyclohexane diacrylate or dimethacrylate, 1,4-butanediol diacrylate or dimethacrylate, 1,6-hexanediol diacrylate or dimethacrylate, neopentyl glycol diacrylate or dimethacrylate, bisphenol A mono- or di-acrylate or methacrylate, benzene trimethacrylate, isobornyl acrylate or methacrylate, acrylamide and derivatives thereof, methacrylamide and derivatives thereof, trimethylolpropane triacrylate or methacrylate, glycerol di- or tri-acrylate or methacrylate, pentaerythritol di-, tri-, or tetra-acrylate or methacrylate, and compounds, such as ethylene oxide or propylene oxide addition products of the above compounds.

The amount of the incorporated monomer having a photopolymerizable unsaturated bond ranges preferably 1 to 50 parts by mass, relative to 100 parts by mass of polyimide precursor (A).

An example is a bifunctional (meth)acrylate. The bifunctional (meth)acrylate means a compound having an acryloyl group or a methacryloyl group at both ends of the molecule thereof. Examples of such compounds include tricyclodecanedimethanol diacrylate, tricyclodecanedimethanol dimethacrylate, tricyclodecanediethanol diacrylate, and tricyclodecanediethanol dimethacrylate.

The bifunctional (meth)acrylate is commercially available, and examples of commercially available products include A-DCP, DCP (each of which is manufactured by Shin-Nakamura Chemical Co., Ltd.), and NEW FRONTIER (registered trademark) HBPE-4 (manufactured by Dai-ich Kogyo Seiyaku Co., Ltd.). These compounds may be used each alone or in combination.

The amount of crosslinkable compound (C) contained in the negative photosensitive resin composition of the present invention is not limited as long as the amount of crosslinkable compound (C) ranges 0.1 to 50 parts by mass, relative to 100 parts by mass of polyimide precursor (A). Especially, the amount of crosslinkable compound (C) ranges preferably 0.5 to 30 parts by mass. When the amount of the incorporated crosslinkable compound (C) is 0.1 part by mass or more, the obtained resin composition exhibits excellent heat resistance and excellent chemical resistance. On the other hand, when the amount of the incorporated crosslinkable compound (C) is 50 parts by mass or less, the obtained resin composition advantageously has excellent storage stability. With respect to the amount of the crosslinkable compound contained, for example, when two or more compounds are used, the total amount of the compounds is used.

[Other Components]

In the embodiment, the resin composition for an insulating film and/or the negative photosensitive resin composition may further contain a component other than the above-mentioned components (A) to (E). Examples of other components include a solvent, a resin component other than the above-mentioned polyimide precursor (A), a sensitizer, a bonding auxiliary, a thermal polymerization inhibitor, an azole compound, a hindered phenol compound, and a filler.

Examples of thermal crosslinking agents include hexamethoxymethylmelamine, tetramethoxymethylglycoluril, tetramethoxymethylbenzoguanamine, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

Examples of fillers include inorganic fillers, specifically, sols, such as silica, aluminum nitride, boron nitride, zirconia, and alumina.

With respect to the solvent, in view of the dissolving power for polyimide precursor (A), an organic solvent is preferably used. Specific examples of organic solvents include N,N-dimethylformamide, N-methyl-2-pyrrolidone, N-ethyl-2-pyrrolidone, N,N-dimethylacetamide, dimethyl sulfoxide, diethylene glycol dimethyl ether, cyclopentanone, cyclohexanone, γ-butyrolactone, α-acetyl-γ-butyrolactone, tetramethylurea, 1,3-dimethyl-2-imidazolinone, and N-cyclohexyl-2-pyrrolidone, and these can be used each alone or in combination.

According to a desired thickness of the applied film of the resin composition for an insulating film and/or the negative photosensitive resin composition and a desired viscosity of the composition, the solvent may be used in an amount, for example, in the range of from 30 to 1,500 parts by mass, preferably in the range of from 100 to 1,000 parts by mass, relative to 100 parts by mass of polyimide precursor (A).

In the embodiment, the resin composition for an insulating film and/or the negative photosensitive resin composition may further contain a resin component other than the above-mentioned polyimide precursor (A). Examples of resin components which may be incorporated into the negative photosensitive resin composition include a polyimide, a polyoxazole, a polyoxazole precursor, a phenolic resin, a polyamide, an epoxy resin, a siloxane resin, and an acrylic resin.

The amount of the above resin component incorporated is preferably in the range of from 0.01 to 20 parts by mass, relative to 100 parts by mass of polyimide precursor (A).

In the embodiment, for improving the photosensitivity, a sensitizer may be optionally incorporated into the resin composition for an insulating film and/or the negative photosensitive resin composition. Examples of the sensitizers include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho(1,2-d)thiazole, and 2-(p-dimethylaminobenzoyl)styrene. These may be used each alone or in combination.

The amount of the sensitizer incorporated ranges preferably 0.1 to 25 parts by mass, relative to 100 parts by mass of polyimide precursor (A).

In the embodiment, for improving the adhesion between a film formed using the resin composition for an insulating film and/or the negative photosensitive resin composition and a substrate, a bonding auxiliary may be optionally incorporated into the resin composition for an insulating film and/or the negative photosensitive resin composition. Examples of bonding auxiliaries include silane coupling agents, such as γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamide acid, benzophenone-3,3′-bis(N-[3-triethoxysilyl]propylamide)-4,4′-dicarboxylic acid, benzene-1,4-bis(N-[3-triethoxysilyl]propylamide)-2,5-dicarboxylic acid, 3-(triethoxysilyl)propylsuccinic anhydride, and N-phenylaminopropyltrimethoxysilane, and aluminum bonding auxiliaries, such as aluminum tris(ethyl acetoacetate), aluminum tris(acetylacetonate), and ethyl acetoacetate aluminum diisopropylate.

Among these bonding auxiliaries, in view of the bonding force, a silane coupling agent is more preferably used. The amount of the bonding auxiliary incorporated is preferably in the range of from 0.5 to 25 parts by mass, relative to 100 parts by mass of polyimide precursor (A).

In the embodiment, for improving the viscosity and photosensitivity stability of the resin composition for an insulating film and/or the negative photosensitive resin composition, especially when stored in the state of a solution containing a solvent, a thermal polymerization inhibitor may be optionally incorporated into the composition.

As a thermal polymerization inhibitor, for example, hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt, or N-nitroso-N(1-naphthyl)hydroxylamine ammonium salt is used.

The amount of the thermal polymerization inhibitor incorporated is preferably in the range of from 0.005 to 12 parts by mass, relative to 100 parts by mass of polyimide precursor (A).

For example, when a substrate formed from copper or a copper alloy is used, in order to suppress discoloration of the substrate, an azole compound may be optionally incorporated into the resin composition for an insulating film and/or the negative photosensitive resin composition. Examples of azole compounds include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole. Especially preferred examples include tolyltriazole, 5-methyl-1H-benzotriazole, and 4-methyl-1H-benzotriazole. These azole compounds may be used each alone or in combination.

The amount of the azole compound incorporated, relative to 100 parts by mass of polyimide precursor (A), ranges preferably 0.1 to 20 parts by mass, and more preferably 0.5 to 5 parts by mass from the viewpoint of the photosensitivity properties. When the amount of the azole compound incorporated is 0.1 part by mass or more, relative to 100 parts by mass of polyimide precursor (A), the obtained negative photosensitive resin composition, which is applied onto copper or a copper alloy, suppresses discoloration of the surface of the copper or copper alloy. On the other hand, when the amount of the azole compound incorporated is 20 parts by mass or less, the obtained negative photosensitive resin composition advantageously has excellent photosensitivity.

In the embodiment, for suppressing discoloration caused on copper, a hindered phenol compound may be optionally incorporated into the negative photosensitive resin composition. Examples of hindered phenol compounds include 2,6-di-t-butyl-4-methylphenol, 2,5-di-t-butyl-hydroquinone, octadecyl-3-(3,5-di-t-butyl-4-hydroxyphenyl) propionate, isooctyl-3-(3,5-di-t-butyl-4-hydroxyphenyl) propionate, 4,4′-methylenebis(2,6-di-t-butylphenol), 4,4′-thio-bis(3-methyl-6-t-butylpheno), 4,4′-butylidene-bis(3-methyl-6-t-butylphenol), triethylene glycol bis[3-(3-t-butyl-5-methyl-4-hydroxyphenyl) propionate], 1,6-hexanediol bis[3-(3,5-di-t-butyl-4-hydroxyphenyl) propionate], 2,2-thio-diethylenebis[3-(3,5-di-t-butyl-4-hydroxyphenyl) propionate], N,N′hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl tetrakis[3-(3,5-di-t-butyl-4-hydroxyphenyl) propionate], tris-(3,5-di-t-butyl-4-hydroxybenzyl) isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H, 5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H, 5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H, 5H)-trione, 1,3,5-tris(4-t-butyl-5,6-diethyl-3-hydroxy-2-methylbenzyl)-1,3,5-triazine-2,4,6-(1H,3H, 5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, and 1,3,5-tris(4-t-butyl-5-ethyl-3-hydroxy-2-methylbenzyl)-1,3,5-triazine-2,4,6-(1H,3H,5H)-trione, but the hindered phenol compound is not limited to these compounds. Of these, especially preferred is 1,3,5-tris(4-t-butyl-3-hydroxy-2,6-dimethylbenzyl)-1,3,5-triazine-2,4,6-(1H,3H,5H)-trione.

The amount of the hindered phenol compound incorporated, relative to 100 parts by mass of polyimide precursor (A), ranges preferably 0.1 to 20 parts by mass, and more preferably 0.5 to 10 parts by mass from the viewpoint of the photosensitivity properties. When the amount of the hindered phenol compound incorporated is 0.1 part by mass or more, relative to 100 parts by mass of polyimide precursor (A), the obtained negative photosensitive resin composition, which is, for example, applied onto copper or a copper alloy, prevents the copper or copper alloy from suffering discoloration or corrosion. On the other hand, when the amount of the hindered phenol compound incorporated is 20 parts by mass or less, the obtained negative photosensitive resin composition advantageously has excellent photosensitivity.

[Method for Producing a Cured Relief Pattern]

In an embodiment, there can be provided a method for producing a cured relief pattern, which comprises the following steps (1) to (4):

(1) applying the photosensitive resin composition for an insulating film of the embodiment onto a substrate to form a photosensitive resin layer for an insulating film on the substrate,

(2) subjecting the photosensitive resin layer for an insulating film to exposure,

(3) subjecting the exposed photosensitive resin layer for an insulating film to development to form a relief pattern, and

(4) subjecting the relief pattern to heating treatment to form a cured relief pattern.

The steps are individually described below.

(1) Step of applying the negative photosensitive resin composition for an insulating film of the embodiment onto a substrate to form a photosensitive resin layer for an insulating film on the substrate

In this step, the photosensitive resin composition for an insulating film of the embodiment is applied onto a substrate, and, if necessary, then dried to form a photosensitive resin layer for an insulating film. As a method for application, a method which has conventionally been used for applying a photosensitive resin composition, for example, a coating method using a spin coater, a bar coater, a blade coater, a curtain coater, or a screen printing machine, or a spray coating method using a spray coater may be used.

If necessary, the film formed from the photosensitive resin composition for an insulating film may be dried, and, as a method for drying, for example, an air-drying, drying by heating using an oven or a hotplate, or vacuum drying method is used. Further, it is desired that drying of the film is conducted under conditions such that polyimide precursor (A) in the negative photosensitive resin composition for an insulating film does not undergo imidization. Specifically, when conducting air-drying or drying by heating, the drying may be conducted under conditions at 20 to 200° C. for one minute to one hour. Thus, a photosensitive resin layer for an insulating film can be formed on the substrate.

(2) Step of Subjecting the Photosensitive Resin Layer for an Insulating Film to Exposure

In this step, the photosensitive resin layer for an insulating film formed in the step (1) above is subjected to exposure through a photomask or reticle having a pattern or directly with, for example, an ultraviolet light source using an exposure apparatus, such as a contact aligner, a mirror projection, or a stepper.

Then, for the purpose of improving the photosensitivity and the like, if necessary, the resultant resin layer may be subjected to post exposure bake (PEB) and/or bake before development having a combination of an arbitrary temperature and time. Preferred baking conditions ares within the range of temperature of 50 to 200° C. and that of time of 10 to 600 seconds, but the baking conditions are not limited to those in the above-mentioned ranges as long as the properties of the negative photosensitive resin composition for an insulating film are not sacrificed.

(3) Step of Subjecting the Exposed Photosensitive Resin Layer for an Insulating Film to Development to Form a Relief Pattern

In this step, the unexposed portion of the exposed photosensitive resin layer is removed by development. As a development method for subjecting the exposed (irradiated) photosensitive resin layer to development, any method may be selected from the conventionally known development methods for photoresist, for example, a rotary spraying method, a paddle method, and an immersion method using an ultrasonic treatment. After the development, for example, for the purpose of adjusting the shape of the relief pattern, if necessary, the resultant relief pattern may be subjected to post development bake having a combination of an arbitrary temperature and time. As a developer used in the development, preferred is, for example, N-methyl-2-pyrrolidone, N-cyclohexyl-2-pyrrolidone, N,N-dimethylacetamide, cyclopentanone, cyclohexanone, γ-butyrolactone, or α-acetyl-γ-butyrolactone. Further, two or more types of the solvents, for example, several types of the solvents may be used in combination.

(4) Step of Subjecting the Relief Pattern to Heating Treatment to Form a Cured Relief Pattern

In this step, the relief pattern obtained in the above-mentioned development is heated to volatilize the photosensitive component and to allow polyimide precursor (A) to undergo imidization, converting the pattern to a cured relief pattern comprising a polyimide. As a heat curing method, any method may be selected from various types of methods using, for example, a hotplate, an oven, or a programed-temperature oven in which setting of a temperature program is possible. The heating may be conducted, for example, under conditions at 130 to 250° C. for 30 minutes to 5 hours. As a gas constituting an atmosphere for the heat curing, air may be used, and an inert gas, such as nitrogen gas or argon gas, may be used.

[Insulating Film for Redistribution in a Semiconductor Device]

The insulating film, which is a baked product of an applied film comprising the resin composition for an insulating film of the present invention, is also advantageously used in a fan out wafer level package (fan out WLP). The fan out WLP is a semiconductor package in which extended portions are formed around a semiconductor chip using an encapsulation resin, such as an epoxy resin, and redistribution is made from the electrodes on the semiconductor chip to the extended portions, and solder balls are mounted on the extended portions to secure the required number of terminals. In the fan out WLP, a wiring is disposed across the boundary between the principal surface of the semiconductor chip and the principal surface of the encapsulation resin. That is, an interlayer dielectric is formed on a substrate comprised of two or more materials, i.e., a semiconductor chip having a metal wiring formed thereon and an encapsulation resin, and a wiring is formed on the interlayer dielectric or between the interlayer dielectric and another one. In a semiconductor package of another type such that a semiconductor chip is embedded in a depressed portion formed in a glass epoxy resin substrate, a wiring is disposed across the boundary between the principal surface of the semiconductor chip and the principal surface of a printed circuit board. Also in this form of the package, an interlayer dielectric is formed on a substrate comprised of two or more materials, and a wiring is formed on the interlayer dielectric or between the interlayer dielectric and another one. The insulating film, which is a baked product of an applied film comprising the resin composition for an insulating film of the present invention, has high adhesion to a semiconductor chip having a metal wiring formed thereon, and further has high adhesion to an encapsulation resin, such as an epoxy resin, and therefore is advantageously used as an interlayer dielectric to be formed on a substrate comprised of two or more materials.

Further, with respect to the fan out WLP, there is present a package of a type which is formed in a process in which a package is disposed as an interlayer dielectric between redistribution layers on a support substrate having placed thereon a temporary adhesive material, and a silicon chip and an encapsulation resin are disposed on the resultant substrate, and then the support substrate having placed thereon a temporary adhesive material and the redistribution layers are peeled off. In a package of this type, rather than a silicon wafer, a glass substrate which is likely to suffer warpage is generally used as a support substrate, and therefore it is preferred that the insulating film has a low stress.

[Semiconductor Device]

In an embodiment, there is provided a semiconductor device which has the resin film for an insulating film of the present invention in at least a part thereof, for example, a semiconductor device which uses the resin film for an insulating film of the present invention as an interlayer dielectric between wirings, for example, an interlayer dielectric between redistribution layers. In the embodiment, there is also provided a semiconductor device having a cured relief pattern obtained by the above-mentioned method for producing a cured relief pattern. Accordingly, there can be provided a semiconductor device having a substrate which is a semiconductor element, and a cured relief pattern of polyimide formed on the substrate by the above-mentioned method for producing a cured relief pattern. Further, the present invention can be applied to a method for producing a semiconductor device, which uses a semiconductor element as a substrate, and which comprises the above-mentioned method for producing a cured relief pattern as one of the steps of the method. The semiconductor device of the present invention can be produced by using the above-mentioned method for producing a cured relief pattern and a known method for producing a semiconductor device in combination, wherein a cured relief pattern is formed by the method for producing a cured relief pattern as, for example, a surface protective film, an interlayer dielectric, an insulating film for redistribution, a protective film for a flip chip device, or a protective film for a semiconductor device having a bump structure.

[Display Device]

In an embodiment, there is provided a display device comprising a display element and a cured film formed on the upper portion of the display element, wherein the cured film is the above-mentioned cured relief pattern. In the display device, the cured relief pattern may be directly stacked on the display element, or may be stacked through another layer on the display element. Examples of the cured films include a surface protective film, an insulating film, and a planarization film for a TFT liquid crystal display element and a color filter element, a bump for an MVA liquid crystal display device, and a barrier for an organic EL element cathode.

The negative photosensitive resin composition of the present invention can be applied to a semiconductor device as mentioned above, and further can be advantageously used in applications of, for example, an interlayer dielectric for a multilayer circuit, a cover coat for a flexible copper-clad sheet, a solder resist film, and a liquid crystal oriented film.

### EXAMPLES

Hereinbelow, the present invention will be described in more detail with reference to the following Examples, which should not be construed as limiting the scope of the present invention.

The weight average molecular weight shown in the following synthesis example in the description is the result of measurement by gel permeation chromatography (hereinafter, referred to simply as “GPC” in the description). In the measurement, a GPC apparatus (HLC-8320GPC), manufactured by Tosoh Corp., is used, and conditions for the measurement and others are as follows.

GPC Column: KD-803, KD-805 (Shodex)

Column temperature: 50° C.

Solvent: N,N-Dimethylformamide (DMF, Kanto Chemical Co., Inc.; special grade reagent (guaranteed reagent)), lithium bromide monohydrate (Kanto Chemical Co., Inc.; Kanto special grade reagent (Cica-reagent)) (30 mM)/phosphoric acid (Aldrich) (30 mM)/tetrahydrofuran (THF, Kanto Chemical Co., Inc.; special grade reagent) (1%)

Flow rate: 1.0 mL/minute

Standard sample: Polystyrene (manufactured by GL Science Inc.)

### <Production Example 1> (Synthesis of Polymer (1A) as a Polyimide Precursor)

40.00 g (0.129 mol) of 4,4′-oxydiphthalic dianhydride (ODPA, Tokyo Chemical Industry Co., Ltd.) was placed in a four-neck flask having a capacity of 1 liter. 16.20 g (0.126 mol) of 2-hydroxyethyl methacrylate (HEMA, Aldrich), 20.75 g (0.126 mol) of triethylene glycol monomethyl ether (Tokyo Chemical Industry Co., Ltd.), and 116 g of γ-butyrolactone (Kanto Chemical Co., Inc.; Kanto special grade reagent) were placed in the flask. The resultant mixture was cooled to 10° C. or lower and stirred. 20.49 g (0.259 mol) of pyridine (Kanto Chemical Co., Inc.; dehydrated) was added to the mixture while stirring. Thereafter, the temperature of the resultant mixture was increased to 25° C., followed by stirring for 23 hours.

Then, a solution obtained by dissolving 52.15 g (0.253 mol) of N,N′-dicyclohexylcarbodiimide (DCC, Kanto Chemical Co., Inc.; Kanto special grade reagent) in 80 g of γ-butyrolactone was dropwise added to the reaction solution at 5° C. or lower over 2 hours while stirring. Subsequently a solution obtained by dissolving 42.32 g (0.116 mol) of 4,4-bis(4-aminophenoxy)biphenyl (BAPB, Seika Corporation) in 80 g of N-methyl-2-pyrrolidinone (NMP, Kanto Chemical Co., Inc.; Kanto special grade reagent) was dropwise added to the resultant mixture over 2 hours while stirring. Then, the temperature of the resultant mixture was increased to 25° C. and the mixture was stirred for 40 hours. Thereafter, 6.0 g of ethanol (Kanto Chemical Co., Inc.; special grade reagent) was added thereto. The resultant mixture was stirred for one hour. Thereafter, 60 g of NMP was added to the mixture. The precipitate formed in the reaction solution was removed by filtration to obtain a reaction mixture.

140 g of tetrahydrofuran (THF, Kanto Chemical Co., Inc.; special grade reagent) was added to the obtained reaction mixture to obtain a crude polymer solution. The obtained crude polymer solution was dropwise added to 6 kg of methanol (Kanto Chemical Co., Inc.; special grade reagent) to allow the polymer to precipitate. The resultant precipitate was collected by filtration, and then subjected to vacuum drying to obtain polymer (1A) in a powdery form. The molecular weight of polymer 1A was measured by GPC (using a conversion calibration curve obtained from the standard polystyrene). As a result, it was found that the weight average molecular weight (Mw) was 20,129. The yield was 72.8%. The reaction product has a repeating unit structure represented by the following formula (1A).

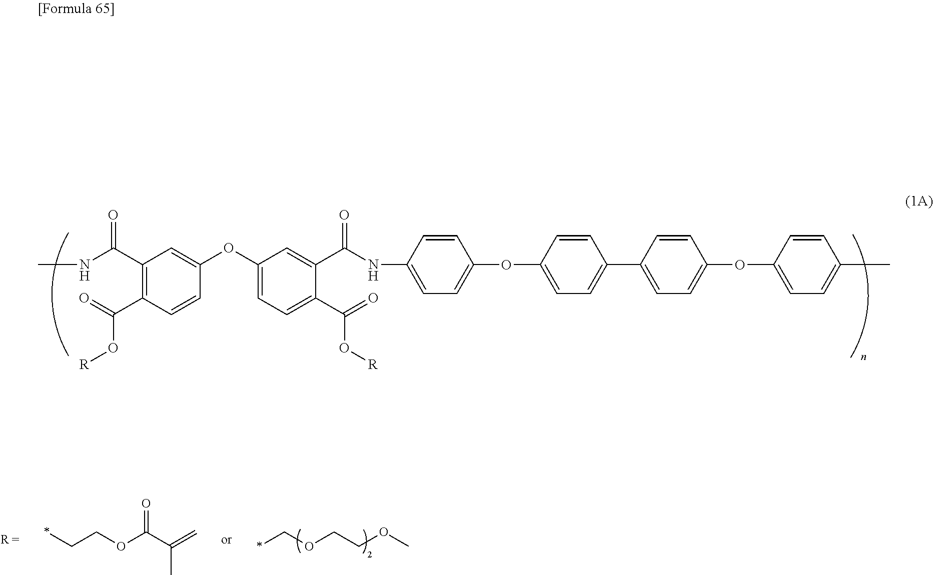

Wherein * is a site bonded to the carboxylic acid of polyimide precursor (1A).

### Example 1

3.50 g of the polymer obtained in Production Example 1 and 0.175 g of N-α-(9-fluorenylmethoxycarbonyl)-N-t-butoxycarbonyl-L-histidine (hereinafter, referred to simply as “Fmoc-His”) were dissolved in 16.74 g of NMP to prepare a composition. Then, the composition was subjected to filtration using a polypropylene microfilter having a pore diameter of 5 μm to prepare a polyimide precursor composition.

### Comparative Example 1

3.50 g of the polymer obtained in Production Example 1 was dissolved in 15.94 g of NMP to prepare a composition. Then, the composition was subjected to filtration using a polypropylene microfilter having a pore diameter of 5 μm to prepare a polyimide precursor composition.

[FT-IR Measurement]

Apparatus: FT/IR 6600 (manufactured by JASCO Corporation)

Measurement method: Transmission method

[Measurement of an Imidization Ratio]

Each of the polyimide precursor compositions obtained in Example 1 and Comparative Example 1 was applied by spin coating onto a silicon substrate. The resultant film was dried on a hotplate at a temperature of 100° C. for 5 minutes, baked at 160° C. for 4 hours, and baked at 300° C. for one hour. Thereafter, the FT-IR spectrum of each film was measured. The imidization ratio was calculated for the film baked at 160° C. for 4 hours. The thickness of the film was adjusted to 1 to 2 μm. The results of the evaluation are shown in Table 1.

TABLE 1

| | Imidization ratio |
|---|---|
| Example 1 | 100% |
| Comparative Example 1 | 71% |

### INDUSTRIAL APPLICABILITY

The resin composition for an insulating film of the present invention can be advantageously used in the field of resin materials for insulating film, which are useful in producing electric and electronic materials for, for example, a semiconductor device and a multilayer circuit board.

1. A resin composition for an insulating film, the resin composition comprising:
(A) a polyimide precursor having a unit structure represented by the following general formula (1): 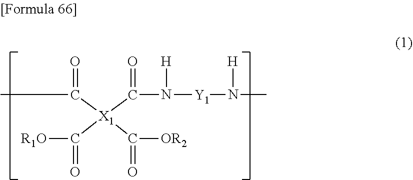
wherein X₁ is a tetravalent organic group having 6 to 40 carbon atoms, Y₁ is a divalent organic group having 6 to 40 carbon atoms, and each of R₁ and R₂ is independently a hydrogen atom or a monovalent organic group selected from the following general formulae (2) and (3): 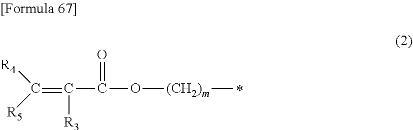
wherein each of R₃, R₄, and R₅ is independently a hydrogen atom or a monovalent organic group having 1 to 3 carbon atoms, m is an integer of 1 to 10, and * is a site bonded to a carboxylic acid present in the polyamic acid main chain of general formula (1),
[Formula 68]
R₆—* (3)
wherein R₆ is a monovalent organic group selected from alkyl groups having 1 to 30 carbon atoms and optionally being interrupted by an ether oxygen atom, and * is as defined above,
wherein a proportion of the total amount of the monovalent organic group represented by general formula (2) above and the monovalent organic group represented by general formula (3) above in the total amount of R₁ and R₂ is 80% by mole or more, and a proportion of the amount of the monovalent organic group represented by general formula (3) above in the total amount of R₁ and R₂ ranges 1 to 100% by mole;
(B) a compound that satisfies all of the following requirements (a) to (d):
(a) having at least one carboxyl group,
(b) having a partial structure represented by formula (N-1) or formula (N-2) below, wherein every structure represented by formula (N-1) is bonded to an aromatic ring or a carbonyl group at at least one site of the structure, or is part of a guanidine scaffold, and every structure represented by formula (N-2) is bonded to a carbon atom having an unsaturated bond at a site of the nitrogen atom, with the proviso that when formula (N-1) is part of a guanidine scaffold, at least one of the two structures (N-1) contained in the guanidine scaffold is bonded to an aromatic ring or a carbonyl group: 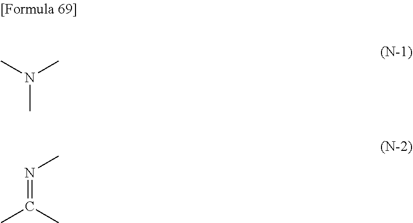
wherein formulae (N-1) and (N-2) represent a trivalent structure in the compound,
(c) at least one partial structure represented by formula (N-1) above being a partial structure of a structure which is represented by the following formula (ND-1), and
which is not directly bonded to an aromatic ring and a carbonyl group, or at least one partial structure represented by formula (N-2) above being a partial structure of a structure represented by the following formula (ND-2): 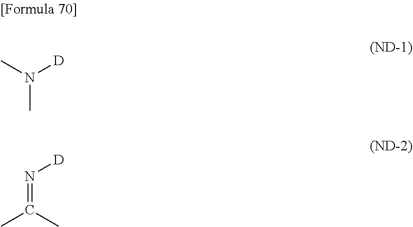
wherein formulae (ND-1) and (ND-2) represent a divalent structure in the compound, and D is a protecting group which is replaceable by a hydrogen atom upon heating,
(d) having, relative to one carboxyl group, at least one structure represented by formula (ND-1) or (ND-2) defined in requirement (c) above; and
(C) an organic solvent.

2. The resin composition for an insulating film according to claim 1, wherein R₆ is selected from two or more different alkyl groups having 1 to 30 carbon atoms and optionally being interrupted by an ether oxygen atom.

3. The resin composition for an insulating film according to claim 1, which is for use in forming a redistribution layer in a production of a semiconductor device.

4. The photosensitive resin composition for an insulating film according to claim 1, further comprising (D) a photopolymerization initiator.

5. A resin film for an insulating film, which is a baked product of an applied film comprising the resin composition for an insulating film according to claim 1.

6. A resin film for an insulating film, which is a baked product of an applied film comprising a resin composition for an insulating film, the resin composition comprising:
(A) a polyimide precursor; and
(B) a compound that satisfies all of the following requirements (a) to (d):
(a) having at least one carboxyl group,
(b) having a partial structure represented by formula (N-1) or formula (N-2) below, wherein every structure represented by formula (N-1) is bonded to an aromatic ring or a carbonyl group at at least one site of the structure, or is part of a guanidine scaffold, and every structure represented by formula (N-2) is bonded to a carbon atom having an unsaturated bond at a site of the nitrogen atom, with the proviso that when formula (N-1) is part of a guanidine scaffold, at least one of the two structures (N-1) contained in the guanidine scaffold is bonded to an aromatic ring or a carbonyl group: 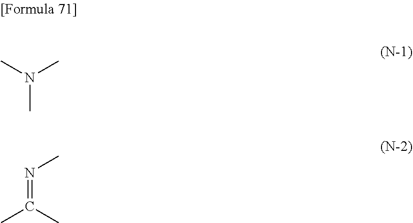
wherein formulae (N-1) and (N-2) represent a trivalent structure in the compound,
(c) at least one partial structure represented by formula (N-1) above being a partial structure of a structure which is represented by the following formula (ND-1), and which is not directly bonded to an aromatic ring and a carbonyl group, or at least one partial structure represented by formula (N-2) above being a partial structure of a structure represented by the following formula (ND-2): 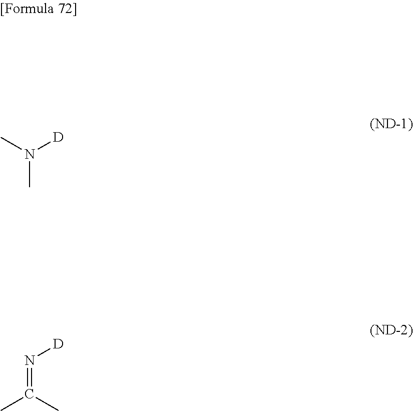
wherein formulae (ND-1) and (ND-2) represent a divalent structure in the compound, and D is a protecting group which is replaceable by a hydrogen atom upon heating,
(d) having, relative to one carboxyl group, at least one structure represented by formula (ND-1) or (ND-2) defined in requirement (c) above,
wherein the resin film has a relative permittivity of 3.5 or less.

7. A semiconductor device having in at least a part thereof the resin film for an insulating film according to claim 5.
